(19) United States
(12) Patent Application Publication
(10) Pub. No.: US 2025/0004332 A1
(43) Pub. Date: Jan. 2, 2025

(54) LIQUID CRYSTAL PANEL AND IMAGE DISPLAY DEVICE

(71) Applicant: Sharp Display Technology Corporation, Kameyama City (JP)

(72) Inventors: Takehisa YOSHIDA, Kameyama City (JP); Fumikazu SHIMOSHIKIRYOH, Kameyama City (JP); Shigeyuki YAMADA, Kameyama City (JP)

(21) Appl. No.: 18/664,285

(22) Filed: May 15, 2024

(30) Foreign Application Priority Data
Jun. 21, 2023 (JP) 2023-101786

(51) Int. Cl. G02F 1/1343; G02F 1/1333

(52) U.S. Cl. CPC G02F 1/134309; G02F 1/133345; G02F 1/13439

(57) ABSTRACT

A liquid crystal panel includes a first transparent substrate, a first electrode, a liquid crystal layer, a second electrode, and a second transparent substrate in this order, in which the liquid crystal layer contains polymer dispersed liquid crystal and/or guest-host liquid crystal containing a dichroic dye, and includes a transparent region and a switching region switched between a transmitting state and a scattering or absorption state by including an overlapping region overlapping the second electrode and a non-overlapping region not overlapping the second electrode.

### CROSS-REFERENCE TO RELATED APPLICATIONS

This application claims the benefit of priority to Japanese Patent Application Number 2023-101786 filed on Jun. 21, 2023. The entire contents of the above-identified application are hereby incorporated by reference.

### BACKGROUND

### Technical Field

The disclosure described below relates to a liquid crystal panel and an image display device.

A liquid crystal panel is an optical element that controls an amount of light transmission by applying a voltage to a liquid crystal composition sealed between a pair of substrates to change an alignment state of liquid crystal molecules in the liquid crystal composition according to the applied voltage. Such liquid crystal panels are used in a wide range of fields of image display devices and the like, taking their advantages of thinness, light weight, and low power consumption.

In recent years, improvement of a viewing angle characteristic of image display devices has been studied so that images can be observed at similar levels in both a narrow viewing angle range and a wide viewing angle range. On the other hand, from a viewpoint of privacy protection, a display method has been studied in which images can be observed in a narrow viewing angle range but are difficult to observe in a wide viewing angle range. Thus, there is a demand for display devices capable of switching between a public mode (also referred to as a wide viewing angle mode) in which images can be observed at similar levels in both the narrow viewing angle range and the wide viewing angle range, and a privacy mode (also referred to as a narrow viewing angle mode) in which images can be observed in the narrow viewing angle range but are difficult to observe in the wide viewing angle range.

Regarding a technique for switching viewing angle modes, for example, JP 2007-206373 A discloses an optical element including, between a pair of transparent substrates, first regions made of a light-transmissive material and a second region disposed between the first regions and containing a liquid crystal material that can be selectively switched between a light-transmitting state and a scattering or absorption state. JP 2005-221756 A discloses a viewing angle control element including a first region having a certain transmittance and a second region that can be switched between another certain transmittance and a transmittance smaller than the other certain transmittance, where the first region and the second region face one pixel.

### SUMMARY

FIG. 20A is a schematic cross-sectional view describing a wide viewing angle mode of an image display device 1R in a comparative embodiment. FIG. 20B is a schematic cross-sectional view describing a narrow viewing angle mode of the image display device 1R in the comparative embodiment. The image display device 1R illustrated in FIGS. 20A and 20B includes, in order from an observation surface side to a back face side, a display panel 10, a liquid crystal panel 20R containing polymer dispersed liquid crystal (PDLC), a louver layer 30R, and a backlight 40.

The display panel 10 includes, in order from the observation surface side to the back face side, a color filter (CF) substrate 110 including a CF layer and a thin film transistor (TFT) substrate 120 including TFTs.

The liquid crystal panel 20R includes, between a pair of transparent substrates 210 and 220, a pair of electrodes 230 and a liquid crystal layer 240R containing the PDLC sandwiched between these electrodes. The PDLC has a configuration in which liquid crystal components are dispersed in a polymer network. As illustrated in FIGS. 20A and 20B, the liquid crystal panel 20R can switch between a transmitting state and a scattering state by using a difference in refractive indexes between the liquid crystal components and the polymer network caused by changing an alignment state of the liquid crystal components by applying a voltage to the liquid crystal layer 240R. When PDLC that scatters light in a no voltage applied state is used, the liquid crystal panel 20R is in a scattering state when no voltage is applied and is in a transmitting state when a voltage is applied.

The louver layer 30R has a configuration in which light blocking portions 31 mainly made of a light absorbing material and transparent portions 32 mainly made of a transparent resin are alternately arranged in parallel. The louver layer 30R has a function of transmitting light 1LA in a front direction and blocking light 1LB in an oblique direction of light from the backlight 40. That is, the louver layer 30R has a function of transmitting light at a low polar angle and blocking light at a high polar angle.

In the image display device 1R, in both the wide viewing angle mode and the narrow viewing angle mode, the light 1LB in the oblique direction from the backlight 40 is blocked (cut) by the louver layer 30R, and only the light 1LA in the front direction passes through the louver layer 30R (see FIGS. 20A and 20B). When no voltage is applied, the light 1LA in the front direction passed through the louver layer 30R is scattered (attenuated) in the liquid crystal panel 20R, so that the light 1LA spreads and enters the display panel 10 (see FIG. 20A). On the other hand, when a voltage is applied, the light 1LA in the front direction passed through the louver layer 30R passes through the liquid crystal panel 20R without being scattered and enters the display panel 10 (see FIG. 20B).

Thus, when no voltage is applied, the image display device 1R can transmit the backlight light from a low polar angle side to a high polar angle side to achieve the wide viewing angle mode, while when a voltage is applied, the image display device 1R does not transmit the backlight light on the high polar angle side but transmits the backlight light only on the low polar angle side to achieve the narrow viewing angle mode. However, the image display device 1R has a problem in that a thickness becomes large because the liquid crystal panel 20R and the louver layer 30R are separately added as components to the display panel 10 in order to switch between the wide viewing angle mode and the narrow viewing angle mode.

In the optical element described in JP 2007-206373 A, the first region in the light-transmitting state and the second region in which the light-transmitting state and the scattering or absorption state are selectively switched are physically distinguished by using different materials for these regions. Such an optical element has various problems for practical application, such as difficulty in narrowing a viewing angle using a normal liquid crystal process and complexity of a manufacturing process.

For example, JP 2007-206373 A states that a UV photosensitive resin is preferable as a light-transmissive material that forms the first region. When a UV photosensitive resin is used, a thickness of a resin layer increases. In this regard, JP 2007-206373 A describes an example in which a height of a pattern of a composite material that forms the second region to obtain a narrow viewing angle (60°) is 300 μm when a width is 10 to 30 μm and a pitch is 200 μm. Although a thickness of the light-transmissive material that forms the first region corresponds to the height of this pattern example, it is difficult to achieve the height of 300 μm using the normal liquid crystal process (typically within 10 μm). Therefore, when a UV photosensitive resin is used as the light-transmissive material, it is difficult to narrow the viewing angle. As the light-transmissive material, a polymer material containing liquid crystal molecules, more specifically, a UV-curable composite material in which liquid crystal molecules are dispersed in an ultraviolet-curable polymer is also exemplified. In this case, in order to make the first region into a light-transmitting state, a process of UV curing by applying a voltage as illustrated in FIG. 11 of JP 2007-206373 A is required. Therefore, the manufacturing process of the optical element becomes complicated.

In the viewing angle control element described in JP 2005-221756 A, for example, the first region is composed of a columnar transmissive resin layer and the second region is composed of a liquid crystal layer. In this case, a fine pattern of the columnar light-transmitting resin layer can be formed with high dimensional accuracy using typical photolithography, so the viewing angle control element can be manufactured without changing an existing liquid crystal manufacturing process. Therefore, the viewing angle control element is highly useful in the field of display devices because the viewing angle control element can achieve both the wide viewing angle and the narrow viewing angle while preventing image quality deterioration due to a decrease in luminance of the image display element during the wide viewing angle. However, there is room for improvement in simplifying the manufacturing process and making it easier to control the viewing angle.

The disclosure has been made in view of the above circumstances, and an object thereof is to provide a liquid crystal panel capable of controlling a viewing angle while suppressing an increase in thickness, and an image display device including the liquid crystal panel.

(1) A liquid crystal panel according to one embodiment of the disclosure, includes a first transparent substrate, a first electrode, a liquid crystal layer, a second electrode, and a second transparent substrate in this order, in which the liquid crystal layer contains polymer dispersed liquid crystal and/or guest-host liquid crystal containing a dichroic dye, and includes a transparent region and a switching region switched between a transmitting state and a scattering or absorption state by including an overlapping region overlapping the second electrode and a non-overlapping region not overlapping the second electrode.

(2) In the liquid crystal panel according to an embodiment of the disclosure, in addition to the configuration in (1), the second electrode is disposed in a stripe shape or a lattice pattern in a plan view.

(3) The liquid crystal panel according to an embodiment of the disclosure, in addition to the configuration in (1) or (2), includes an interlayer insulating film and a third electrode provided in this order from a side of the second electrode between the second electrode and the second transparent substrate.

(4) In the liquid crystal panel according to an embodiment of the disclosure, in addition to the configuration in (3), the transparent region and the switching region are configured to be applied with different voltages.

(5) In the liquid crystal panel according to an embodiment of the disclosure, in addition to the configuration in (1), (2), (3), or (4), a thickness of the non-overlapping region is 30 μm or less.

(6) In the liquid crystal panel according to an embodiment of the disclosure, in addition to the configuration in (1), (2), (3), (4), or (5), the second electrode is a transparent electrode or an electrode including a light absorbing material.

(7) An image display device according to an embodiment of the disclosure includes the liquid crystal panel in (1), (2), (3), (4), (5), or (6) and a display panel configured to display an image.

(8) The image display device according to an embodiment of the disclosure, in addition to the configuration in (7), further includes a backlight.

(9) In the image display device according to an embodiment of the disclosure, in addition to the configuration in (8), the backlight has a local dimming function.

(10) In the image display device according to an embodiment of the disclosure, in addition to the configuration in (7), (8), or (9), the display panel is a liquid crystal display panel or a self-luminous display panel.

According to the disclosure, it is possible to provide a liquid crystal panel capable of controlling a viewing angle while suppressing an increase in thickness, and an image display device including the liquid crystal panel.

### BRIEF DESCRIPTION OF DRAWINGS

The disclosure will be described with reference to the accompanying drawings, wherein like numbers reference like elements.

FIG. 1 is a schematic cross-sectional view of a liquid crystal panel according to a first embodiment (Example 1).

FIG. 2A is a schematic cross-sectional view illustrating a wide viewing angle mode of the liquid crystal panel according to the first embodiment.

FIG. 2B is a schematic cross-sectional view illustrating a narrow viewing angle mode of the liquid crystal panel according to the first embodiment.

FIG. 3 is a conceptual diagram for explaining a thickness D of a non-overlapping region, a width W1 of the non-overlapping region, a width W2 of an overlapping region, and a viewing angle θ.

FIG. 4 is a schematic cross-sectional view of an image display device according to the first embodiment.

FIG. 5A is a schematic cross-sectional view illustrating a wide viewing angle mode of the image display device according to the first embodiment.

FIG. 5B is a schematic cross-sectional view illustrating a narrow viewing angle mode of the image display device according to the first embodiment.

FIG. 6 is a schematic cross-sectional view of an image display device according to a modified example of the first embodiment.

FIG. 7 is a schematic plan view illustrating an arrangement pattern of a second electrode in the liquid crystal panel according to the first embodiment.

FIG. 8 is a schematic plan view illustrating an arrangement pattern of a second electrode in a liquid crystal panel according to a second embodiment (Example 2).

FIG. 9 is a schematic cross-sectional view of a liquid crystal panel according to a third embodiment (Example 3).

FIG. 10A is a schematic cross-sectional view of a liquid crystal panel according to a fourth embodiment (Example 4-1).

FIG. 10B is a schematic cross-sectional view of a liquid crystal panel according to a modified example of the fourth embodiment (Example 4-2).

FIG. 11A is a schematic cross-sectional view illustrating a wide viewing angle mode of a liquid crystal panel according to a fifth embodiment (Example 5).

FIG. 11B is a schematic cross-sectional view illustrating a narrow viewing angle mode of the liquid crystal panel according to the fifth embodiment.

FIG. 12A is a schematic cross-sectional view illustrating a wide viewing angle mode of a liquid crystal panel according to a sixth embodiment (Example 6).

FIG. 12B is a schematic cross-sectional view illustrating a narrow viewing angle mode of the liquid crystal panel according to the sixth embodiment.

FIG. 13A is a schematic cross-sectional view illustrating a wide viewing angle mode of a liquid crystal panel according to a seventh embodiment (Example 7).

FIG. 13B is a schematic cross-sectional view illustrating a narrow viewing angle mode of the liquid crystal panel according to the seventh embodiment.

FIG. 14A is a schematic cross-sectional view illustrating a wide viewing angle mode of a liquid crystal panel according to an eighth embodiment (Example 8).

FIG. 14B is a schematic cross-sectional view illustrating a narrow viewing angle mode of the liquid crystal panel according to the eighth embodiment.

FIG. 15A is a schematic cross-sectional view illustrating a wide viewing angle mode of a liquid crystal panel according to a ninth embodiment (Example 9).

FIG. 15B is a schematic cross-sectional view illustrating a narrow viewing angle mode of the liquid crystal panel according to the ninth embodiment.

FIG. 16 is a schematic cross-sectional view of an image display device according to an eleventh embodiment (Example 11).

FIG. 17A shows waveform diagrams of voltages of respective electrodes in a wide viewing angle mode in an image display device according to Example 1.

FIG. 17B shows waveform diagrams of voltages of the respective electrodes in a narrow viewing angle mode in the image display device according to Example 1.

FIG. 18A shows waveform diagrams of voltages of respective electrodes in a wide viewing angle mode in an image display device according to Example 7.

FIG. 18B shows waveform diagrams of voltages of the respective electrodes in a narrow viewing angle mode in the image display device according to Example 7.

FIG. 19A shows waveform diagrams of voltages of respective electrodes in a wide viewing angle mode in an image display device according to Example 8.

FIG. 19B shows waveform diagrams of voltages of the respective electrodes in a narrow viewing angle mode in the image display device according to Example 8.

FIG. 20A is a schematic cross-sectional view illustrating a wide viewing angle mode of an image display device according to a comparative embodiment.

FIG. 20B is a schematic cross-sectional view illustrating a narrow viewing angle mode of the image display device according to the comparative embodiment.

### DESCRIPTION OF EMBODIMENTS

### Definitions of Terms

In this specification, “observation surface side” means a side closer to a screen (display surface) in an image display device, and “back face side” means a side farther from the screen (display surface) in the image display device.

“Polar angle” means an angle between a target direction (e.g., a measurement direction) and a normal direction of a panel surface of a liquid crystal panel. “Azimuthal direction (φ)” means a direction when a target direction is projected onto a screen of the liquid crystal panel, and is expressed by an angle between the target direction and a reference azimuthal direction (azimuth angle). Here, the reference azimuthal direction (φ=0°) is set to a horizontal right direction of the screen of the liquid crystal panel. For angles and azimuthal angles, “counterclockwise” from the reference azimuthal direction is a positive angle and “clockwise” from the reference azimuthal direction is a negative angle. Both the counterclockwise direction and the clockwise direction represent rotation directions when the screen of the liquid crystal panel is viewed from the observation surface side (front). The angle represents a value measured when the screen of the liquid crystal panel is viewed in a plan view.

In this specification, “parallel to each other” means that an angle (absolute value) between them is within a range of 0°±3°. The angle between them is preferably within a range of 0°±1°, more preferably within a range of 0°±0.5°, and particularly preferably 0° (completely parallel).

“No voltage applied state” means a state in which a voltage applied to a liquid crystal layer is less than a threshold voltage (including no voltage applied). “Voltage applied state” means a state in which a voltage applied to the liquid crystal layer is equal to or higher than the threshold voltage. In this specification, “no voltage applied state” is also referred to as “when no voltage is applied”, and “voltage applied state” is also referred to as “when a voltage is applied”.

For a light transmittance, a light transmittance of a sample was calculated by separately measuring a luminance of an LED backlight and a luminance of the sample placed on the LED backlight, and normalizing with the measured luminance of the LED backlight. A spectrophotometer SR-UL1 manufactured by TOPCON CORPORATION was used for measurement. A light reflectance was measured using a spectrophotometer CM-2600d manufactured by KONICA MINOLTA INC. (wavelength range: 360 nm to 740 nm, integrating sphere type).

Embodiments according to the disclosure will be described hereinafter. The technology according to the disclosure is not limited to the contents described in the following embodiments, and appropriate design changes can be made within a scope that satisfies the configuration according to the disclosure.

### First Embodiment

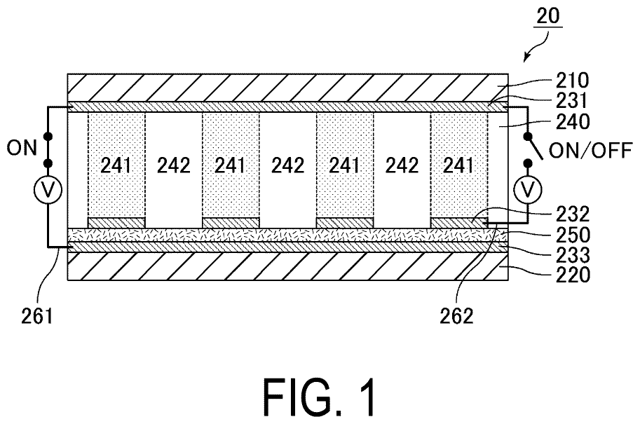

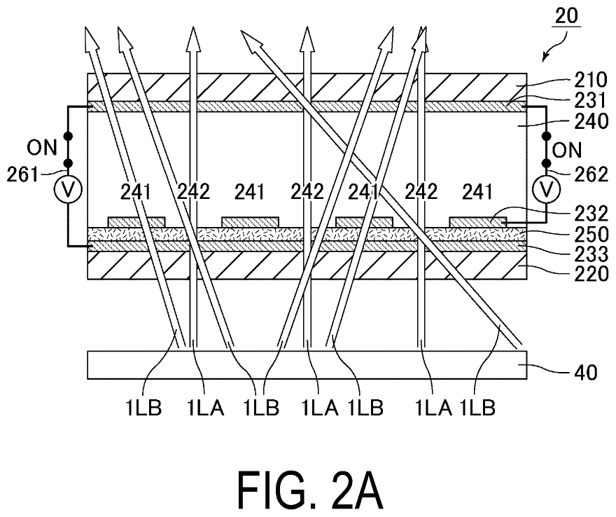

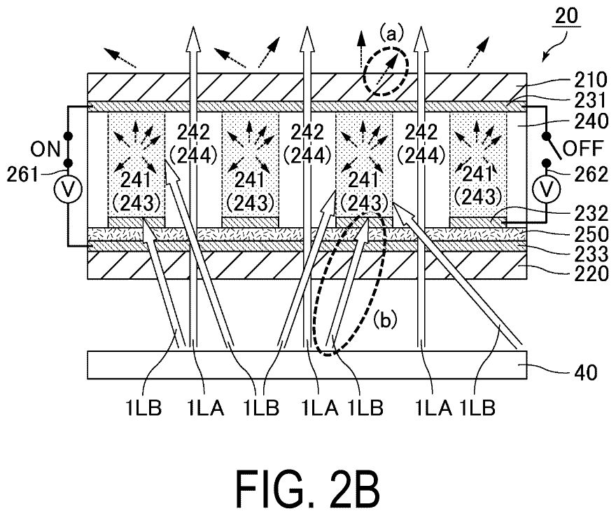

FIG. 1 is a schematic cross-sectional view of a liquid crystal panel according to the present embodiment. FIG. 2A is a schematic cross-sectional view illustrating a wide viewing angle mode of the liquid crystal panel according to the present embodiment. FIG. 2B is a schematic cross-sectional view illustrating a narrow viewing angle mode of the liquid crystal panel according to the present embodiment. As illustrated in FIGS. 1, 2A, and 2B, a liquid crystal panel 20 in the present embodiment includes a first transparent substrate 210, a first electrode 231, a liquid crystal layer 240, a second electrode 232, and a second transparent substrate 220 in this order. An interlayer insulating film 250 and a third electrode 233 are further provided in this order from a second electrode 232 side between the second electrode 232 and the second transparent substrate 220. Since the liquid crystal panel 20 has a function of controlling the viewing angle, the liquid crystal panel 20 can be referred to as a “viewing angle control cell”.

The liquid crystal layer 240 contains polymer dispersed liquid crystal (hereinafter, also referred to as “PDLC”). In the present embodiment, PDLC that scatters light in a no voltage applied state is used.

The liquid crystal layer 240 includes an overlapping region 241 overlapping the second electrode 232 and a non-overlapping region 242 not overlapping the second electrode 232. Since the liquid crystal layer 240 contains the PDLC and includes the overlapping region 241 and the non-overlapping region 242, the liquid crystal layer 240 includes a transparent region 244 and a switching region 243 that is switched between a transmitting state and a scattering state. Depending on design of a power supply, the overlapping region 241 can be the switching region 243 and the non-overlapping region 242 can be the transparent region 244, or the overlapping region 241 can be the transparent region 244 and the non-overlapping region 242 can be the switching region 243. In the present embodiment, the switching region 243 is designed to be switched between the transmitting state and the scattering state by applying or not applying a voltage between the first electrode 231 and the second electrode 232 (262), so that the overlapping region 241 becomes the switching region 243 and the non-overlapping region 242 becomes the transparent region 244 (see FIGS. 1, 2A, and 2B). However, in reality, not only the overlapping region 241 becomes the switching region 243, but also a boundary portion between the overlapping region 241 and the non-overlapping region 242 may become the switching region 243 or another portion may become the switching region 243 depending on an electrical field between the electrodes.

An important point in the disclosure is that the liquid crystal layer 240 contains predetermined liquid crystal and includes the overlapping region 241 overlapping the second electrode 232 and the non-overlapping region 242 not overlapping the second electrode 232, whereby the liquid crystal layer 240 includes the transparent region 244 and the switching region 243 that can be switched between the transmitting state and the scattering (or absorption) state. That is, an important feature of the disclosure is that by applying voltages to the electrodes, the transparent region 244 having a high transmittance and the scattering region (or an absorption region) having a low transmittance are formed in the liquid crystal layer 240, so that the liquid crystal layer 240 itself can act as a louver which can switch on and off. Therefore, positions of the transparent region 244 and the switching region 243 and which regions correspond to the transparent region 244 and the switching region 243 are not limited. That is, the transparent region 244 and the switching region 243 are not limited to the embodiment illustrated in FIGS. 1, 2A, and 2B, and can be appropriately controlled by, for example, a width and a pitch of the second electrode 232, a cell thickness (i.e., a thickness D of the non-overlapping region 242), voltages applied to the electrodes, and the like.

In the present embodiment, the second electrode 232 and the third electrode 233 are disposed with the interlayer insulating film 250 interposed therebetween. In this case, the first electrode 231 functions as a common electrode, the first electrode 231 and the third electrode 233 can control whether voltage is applied or not applied to the non-overlapping region 242 (transparent region 244), and the first electrode 231 and the second electrode 232 can control whether voltage is applied or not applied to the overlapping region 241 (switching region 243). Therefore, in the present embodiment, different voltages can be applied to the transparent region 244 and the switching region 243. Such an electrode structure that is compatible with various driving methods in the field of image display devices is very useful.

The transparent region 244 is a region that exhibits a transmitting state when a voltage is applied between the first electrode 231 and the third electrode 233 (261). The transmitting state is a state that is transparent to light. On the other hand, the switching region 243 is a region that is switched between the transmitting state and the scattering or absorption state. In the present embodiment using the PDLC, the switching region 243 is a region that is switched between the transmitting state and the scattering state. The scattering state is a state in which light is scattered, and a transmittance is lower than that in the transmitting state. In the present embodiment, the liquid crystal layer 240 in the scattering state is in a state similar to frosted glass.

In the present embodiment, as will be described later, in the wide viewing angle mode (see FIG. 2A), the transparent region 244 and the switching region 243 have a certain transmittance (also referred to as visible light transmittance or light transmittance) T1. On the other hand, in the narrow viewing angle mode (see FIG. 2B), the transparent region 244 has a transmittance T2, and the switching region 243 has a transmittance T3 due to scattering (where T1, T2, and T3 satisfy a relationship of “T1≥T2>T3”). The transmittance T1 may be 100%. T3 may be 0%.

As illustrated in FIGS. 2A and 2B, light enters the liquid crystal panel 20 from the back face side (specifically, the backlight 40). In a case in which the liquid crystal layer 240 contains the PDLC that has a property of scattering light when no voltage is applied, when a voltage is applied between the first electrode 231 and the second electrode 232 (262) and a voltage is applied between the first electrode 231 and the third electrode 233 (261) (voltage applied state), the overlapping region 241 and the non-overlapping region 242 are integrated without being distinguished from each other, and an entire liquid crystal layer 240 is in a transmitting state (transparent region) (see FIG. 2A). That is, the transparent region 244 and the switching region 243 are in a state having the transmittance T1. In this case, both light in a front direction and light in an oblique direction that enter the liquid crystal panel 20 from the backlight 40 pass directly through the liquid crystal panel 20 (see FIG. 2A). As a result, the light from the back face side (specifically, the backlight 40) can be transmitted without loss from a low polar angle side to a high polar angle side, enabling a wide viewing angle mode with high luminance.

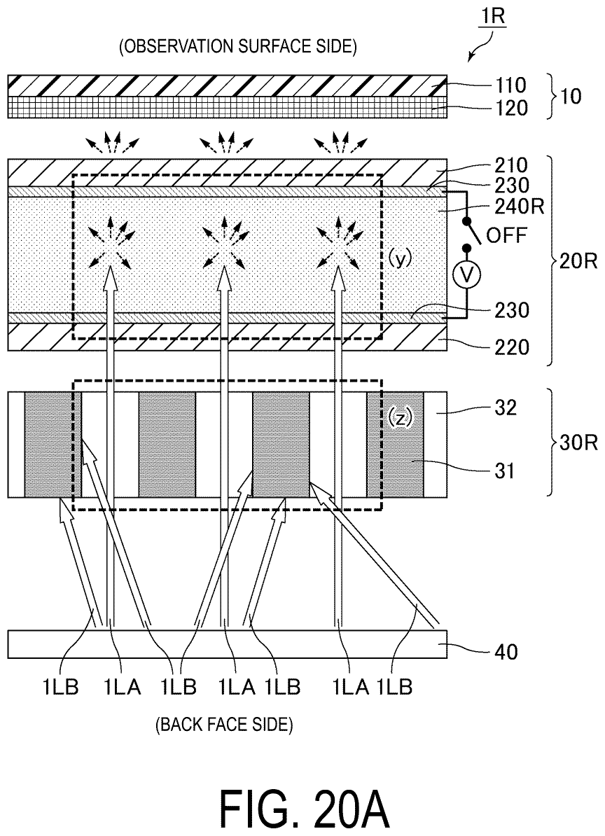

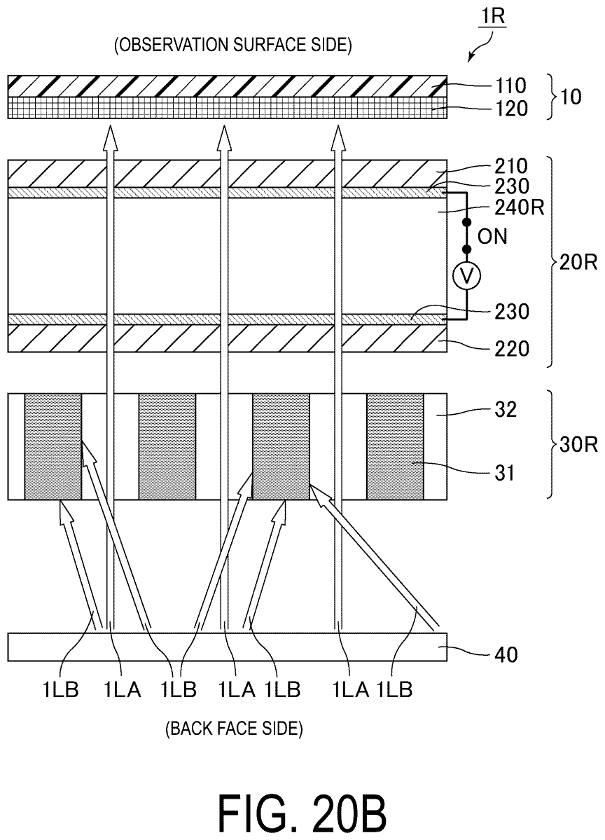

Here, in the image display device 1R in the comparative embodiment, the louver layer 30R cuts the light 1LB in the oblique direction in the wide viewing angle mode even though it is not necessary to cut the light 1LB in the wide viewing angle mode (see part (z) in FIG. 20A). Further, in order to spread the light focused by the louver layer 30R again, the light is scattered (attenuated) by the PDLC layer 240R (see part (y) in FIG. 20A). Accordingly, transmission losses occur in both the louver layer 30R and the PDLC layer 240R, and thus, luminance in the wide viewing angle mode is not sufficient. On the other hand, as described above, the liquid crystal panel 20 in the present embodiment can transmit the light from the backlight 40 without loss, thus enabling the wide viewing angle mode with high luminance.

In the present embodiment, when no voltage is applied between the first electrode 231 and the second electrode 232 (262) and when a voltage is applied between the first electrode 231 and the third electrode 233 (261) (no voltage applied state), the liquid crystal layer 240 itself acts as the louver. That is, of the light that enters the liquid crystal layer 240 from the backlight 40, light 1LB in the oblique direction is scattered (attenuated) in the overlapping region 241 (switching region 243) and passes through the liquid crystal panel 20 as attenuated light (see (a) in FIG. 2B). Here, the overlapping region 241 (switching region 243) is in the scattering state, whereas the non-overlapping region 242 (transparent region 244) remains in the transmitting state. That is, the transparent region 244 has the transmittance T2, and the switching region 243 has the transmittance T3 due to scattering (where T1≥T2>T3). Of the light that enters the liquid crystal layer 240 from the backlight 40, light 1LA in the front direction passes through the liquid crystal panel 20 without being attenuated (see FIG. 2B). As a result, the light from the back face side (specifically, the backlight 40) is attenuated on the high polar angle side, and the light from the back face side can be transmitted with the same luminance only on the low polar angle side, thus enabling the narrow viewing angle mode.

Thus, the liquid crystal panel 20 in the present embodiment has a function of controlling the viewing angle by applying or not applying a voltage, and also has a louver function in addition to this function. Therefore, in the present embodiment, an increase in thickness, weight, and manufacturing costs of the liquid crystal panel and the image display device including the liquid crystal panel can also be suppressed as compared with the image display device 1R in the comparative embodiment including the liquid crystal panel 20R and the louver layer 30R separately (see FIGS. 20A and 20B).

The overlapping region 241 is a region of the liquid crystal layer 240 that overlaps the second electrode 232. “Overlapping the second electrode 232” means being in direct or indirect contact with the second electrode 232. Examples of a configuration in which the second electrode 232 is in indirect contact include a configuration in which the overlapping region 241 and the second electrode 232 are in contact with each other with an alignment film interposed therebetween. The alignment film is a film that has a function of controlling the alignment of liquid crystal molecules contained in the liquid crystal layer 240. On the other hand, the non-overlapping region 242 is a region of the liquid crystal layer 240 that does not overlap the second electrode 232.

The thickness D of the non-overlapping region 242 is preferably 100 μm or less, for example. The thickness D is more preferably 50 μm or less, still more preferably 30 μm or less, particularly preferably 20 μm or less, and most preferably 10 μm or less. Thus, the liquid crystal panel in the present embodiment is compatible with a normal liquid crystal process (typically within 10 μm) and has excellent viewing angle performance. A lower limit of the thickness is not limited, but is preferably 1 μm or more, for example.

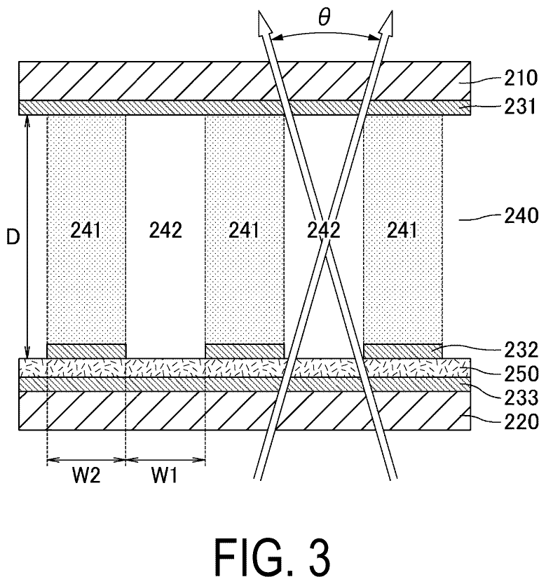

The thickness of the non-overlapping region 242 is also referred to as a height of the non-overlapping region 242. The thickness of the non-overlapping region 242 corresponds to a distance D between the first electrode 231 and the interlayer insulating film 250 in FIG. 3.

The pitch of the non-overlapping region 242 is preferably smaller than a pixel pitch of the display panel 10. Thus, occurrence of moire can be sufficiently suppressed. In particular, it is preferable that the pixel pitch of the display panel 10 be an integral multiple of the pitch of the non-overlapping region 242. The pixel pitch is more preferably 1 to 50 times the pitch of the non-overlapping region, and still more preferably 6 to 24 times the pitch of the non-overlapping region.

A width W1 of the non-overlapping region 242 and a width W2 of the overlapping region 241 can be set as appropriate in accordance with a desired viewing angle. For example, a ratio (W1/W2) may be 100/1 to 100/500 or may be 100/50 to 100/300.

A viewing angle θ of the liquid crystal panel 20 in the narrow viewing angle mode can be freely set by the thickness D and the width W1 of the non-overlapping region 242. Specifically, the viewing angle θ can be set by the following equation (1):

$$θ = 2 {tan}^{- 1} ( W 1 / D ) \qquad ( 1 )$$

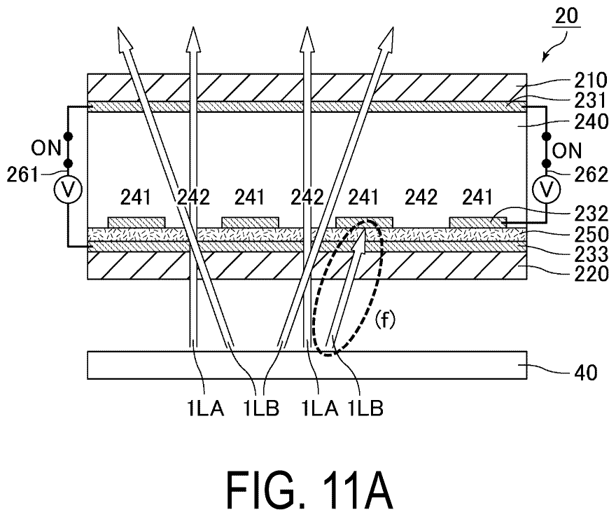

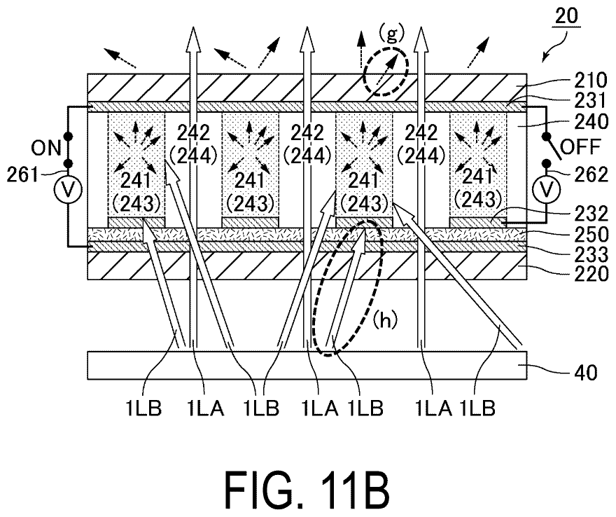

The liquid crystal panel 20 in the present embodiment is compatible with the normal liquid crystal process (typically within 10 μm) as described above, so the narrow viewing angle mode can be easily achieved and the viewing angle performance is excellent. In addition, in the present embodiment, the transparent region 244 and the switching region 243 are not physically distinguished by materials but by the design of the power supply (e.g., arrangement of the electrodes). The transparent region 244 and the switching region 243 are formed of the same material. Therefore, in the present embodiment, there is no need for a UV curing process for fixing the transparent region to the transmitting state in advance during manufacturing as illustrated in FIG. 11 in JP 2007-206373 A, for example. Therefore, the liquid crystal panel 20 in the present embodiment is also advantageous in that the manufacturing processes of the liquid crystal panel and the image display device can be simplified. The liquid crystal panel 20 in the present embodiment will be further described below.

The first transparent substrate 210 and the second transparent substrate 220 may be any substrates that are transparent to visible light. Examples include glass substrates and plastic substrates.

The first electrode 231 is disposed in a planar shape on an entire surface of the first transparent substrate 210. In other words, the first electrode 231 is a solid electrode that covers the first transparent substrate 210. Thus, the entire liquid crystal panel can be switched between the wide viewing angle mode and the narrow viewing angle mode. The first electrode 231 may be a transparent electrode. The transparent electrode can be made of, for example, a transparent conductive material such as indium tin oxide (ITO), indium zinc oxide (IZO), zinc oxide (ZnO), tin oxide (SnO), or an alloy thereof.

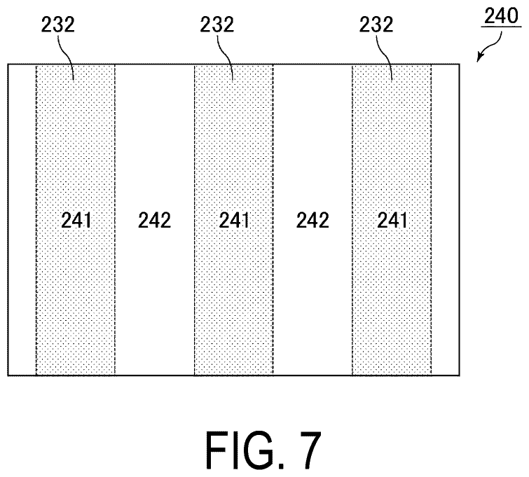

The second electrode 232 is disposed to have a space so that the liquid crystal layer 240 can be divided into the overlapping region 241 that overlaps the second electrode and the non-overlapping region 242 that does not overlap the second electrode. In the present embodiment, as illustrated in FIG. 7, the second electrode 232 is arranged in a stripe shape (also referred to as a slit shape) in a plan view. With such an arrangement, the viewing angle of the screen in a horizontal direction can be controlled. A transparent electrode is used as the second electrode 232 in the present embodiment. Examples of the transparent electrode are as described above.

In the present embodiment, the third electrode 233 is disposed in a planar shape on an entire surface of the second transparent substrate 220. In other words, the third electrode 233 is a solid electrode that covers the second transparent substrate 220. The third electrode 233 may be a transparent electrode. Examples of the transparent electrode are as described above.

The liquid crystal layer 240 contains the PDLC in the present embodiment. The PDLC contains a polymer network and liquid crystal components. In the PDLC, a fibrous matrix of cured photopolymerizable liquid crystal compounds aggregates to form a three-dimensionally continuous polymer network, and the liquid crystal components are phase-separated in the polymer network.

The photopolymerizable liquid crystal compounds for forming the polymer network are, for example, compounds that exhibit a liquid crystal phase at room temperature, are miscible with the liquid crystal components, and phase-separate from the liquid crystal components when cured by ultraviolet irradiation to form a polymer.

Specific examples of the photopolymerizable liquid crystal compounds include monomers including: substituents (also referred to as “mesogenic groups”) such as a biphenyl group, a terphenyl group, a naphthalene group, a phenyl benzoate group, an azobenzene group, and derivatives thereof; photoreactive groups such as a cinnamoyl group, a chalcone group, a cinnamylidene group, a β-(2-phenyl)acryloyl group, a cinnamic acid group, and derivatives thereof; and polymerizable groups such as an acrylate group, a methacrylate group, a maleimide group, an N-phenylmaleimide group, and a siloxane group. The acrylate group is preferred among them. The number of polymerizable groups per molecule of the photopolymerizable liquid crystal compound is not particularly limited, but is preferably one or two.

The liquid crystal component does not need to contain a polymerizable group such as an acrylate group, a methacrylate group, a maleimide group, an N-phenylmaleimide group, or a siloxane group.

In the present embodiment, the liquid crystal component (also referred to as liquid crystal molecule) may have a positive value or a negative value of an anisotropy of dielectric constant (Δε) defined by the following equation (L). The liquid crystal component having positive anisotropy of dielectric constant is aligned in a direction parallel to the electrical field direction, and the liquid crystal component having negative anisotropy of dielectric constant is aligned in a direction perpendicular to the electrical field direction. Note that the liquid crystal component having positive anisotropy of dielectric constant is also referred to as a positive liquid crystal, and the liquid crystal component having negative anisotropy of dielectric constant is also referred to as a negative liquid crystal. A major axis direction of the liquid crystal component is a direction of a slow axis. The major axis direction of the liquid crystal component when no voltage is applied is also referred to as a direction of an initial alignment of the liquid crystal component.

$$Δε = ( dielectric constant of the liquid crystal component in the major axis direction ) - ( dielectric constant of the liquid crystal component in a minor axis direction ) \qquad ( L )$$

As the liquid crystal component, for example, a tolan-based liquid crystal material (a liquid crystal material having —C≡C— (carbon-carbon triple bond) as a linking group) can be used.

A refractive index anisotropy Δn of the liquid crystal component is preferably from 0.18 to 0.24, the anisotropy of dielectric constant ac of the liquid crystal component is preferably from 15 to 25, and a rotational viscosity γ1 of the liquid crystal component is preferably from 100 mPa·s to 300 mPa·s. With such an aspect, strong scattering and low voltage driving can be effectively achieved in a compatible manner, and a response speed equivalent to that of a typical image display device that does not contain a polymer network can be achieved. Such an effect can be effectively achieved when the refractive index anisotropy Δn, the anisotropy of dielectric constant Δε, and the rotational viscosity γ1 of the liquid crystal component are all within the ranges described above.

Specific examples of the tolan-based liquid crystal material include liquid crystal materials having a structure represented by the following general formula (L1).

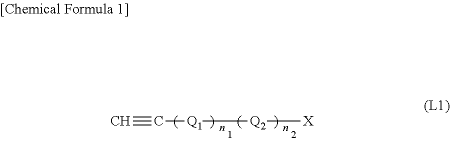

(In the above equation, Q₁ and Q₂ each independently represent an aromatic ring group, X represents a fluorine group or a cyano group, and n₁ and n₂ each independently represent 0 or 1.)

In general formula (L1) above, n₁ and n₂ are not simultaneously 0. That is, the sum of n₁ and n₂ is 1 or 2.

The aromatic ring group in general formula (L1) above may have a substituent.

In general formula (L1) above, preferably, Q₁ and Q₂ are each independently a structure of any of the following general formulas (L2-1) to (L2-7).

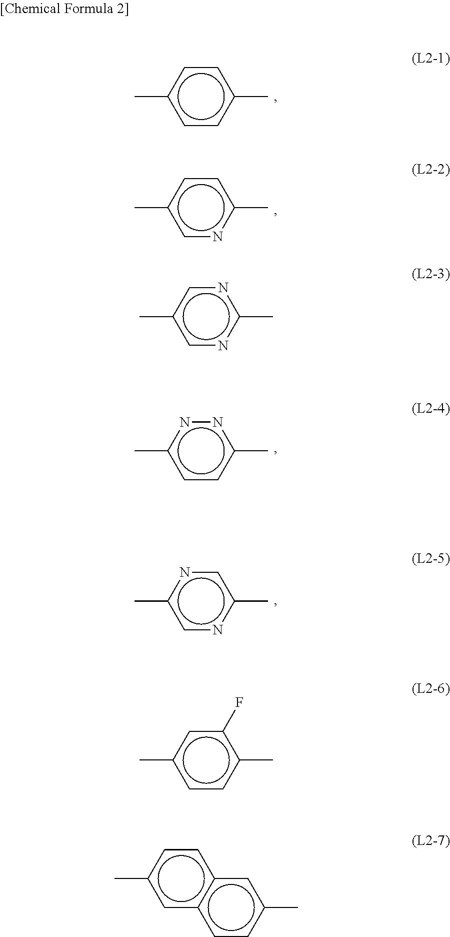

Examples of specific structures of the liquid crystal material having a structure represented by the above general formula (L1) include structures represented by the following chemical formulas (L1-1) to (L1-21).

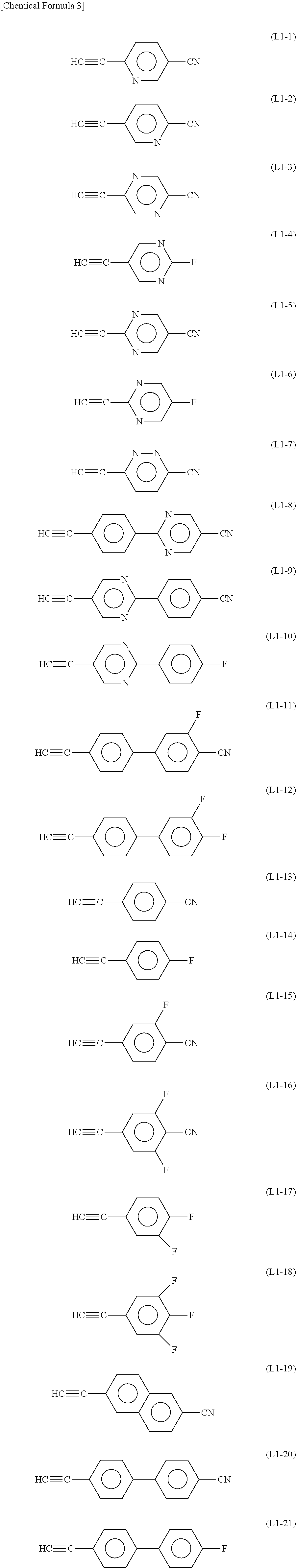

A weight ratio of the liquid crystal components to the polymer network (liquid crystal components/polymer network) is preferably from 90/10 to 97/3. In other words, preferably, a weight percentage of the liquid crystal components is from 90 to 97, and when the weight percentage of the liquid crystal components is 90 or greater, a weight percentage of the polymer network is 10 or less, and when the weight percentage of the liquid crystal components is 97 or less, the weight percentage of the polymer network is 3 or greater. With such an aspect, strong scattering and low voltage driving can be effectively achieved in a compatible manner. When the weight percentage of the polymer network exceeds 10, strong scattering may be obtained, but the drive voltage may increase, while the weight percentage of the polymer network is less than 3, the drive voltage may be reduced, but strong scattering may not be obtained.

For the interlayer insulating film 250, any one of an organic insulating film, an inorganic insulating film, or a layered body of an organic insulating film and an inorganic insulating film can be used. Examples of the organic insulating film that can be used include organic films (relative dielectric constant ε=2 to 5) such as acrylic resins, polyimide resins, and novolac resins, and layered bodies thereof. A film thickness of the organic insulating film is not limited, but is, for example, from 2 μm to 4 μm. Examples of the inorganic insulating film that can be used include inorganic films (relative dielectric constant ε=5 to 7) such as silicon nitride (SiNx) and silicon oxide (SiO2), and layered films thereof. A film thickness of the inorganic insulating film is not limited, but is, for example, from 1500 Å to 3500 Å.

A film thickness of the interlayer insulating film 250 is preferably from 0.1 μm to 4 μm. More preferably, the film thickness is from 0.15 μm to 0.35 μm.

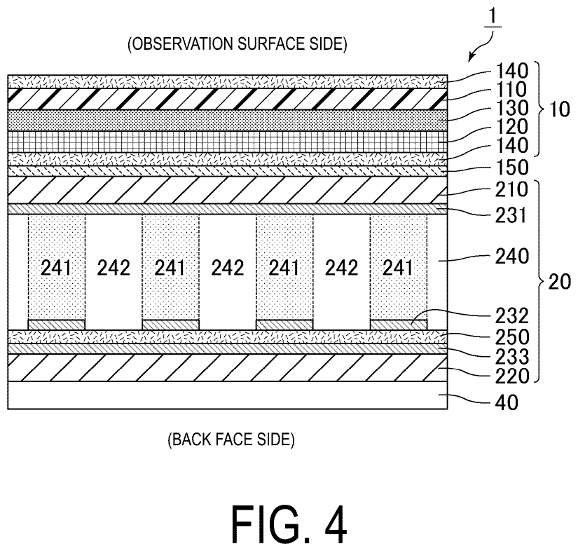

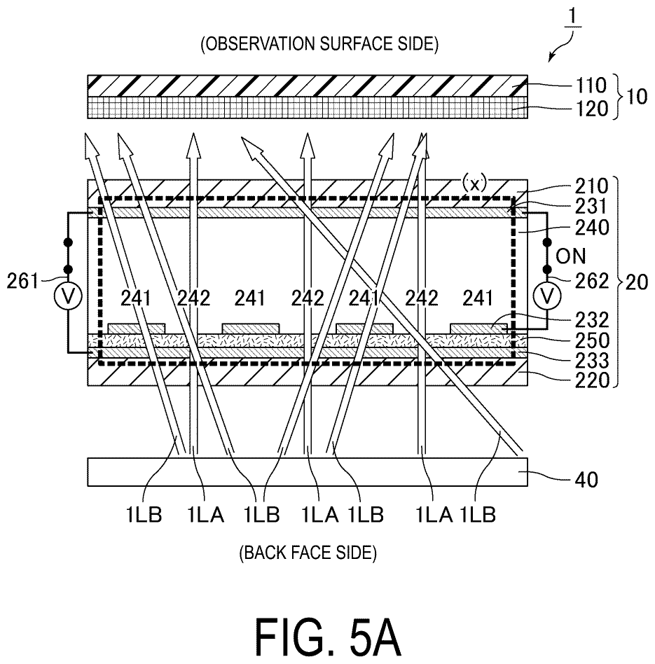

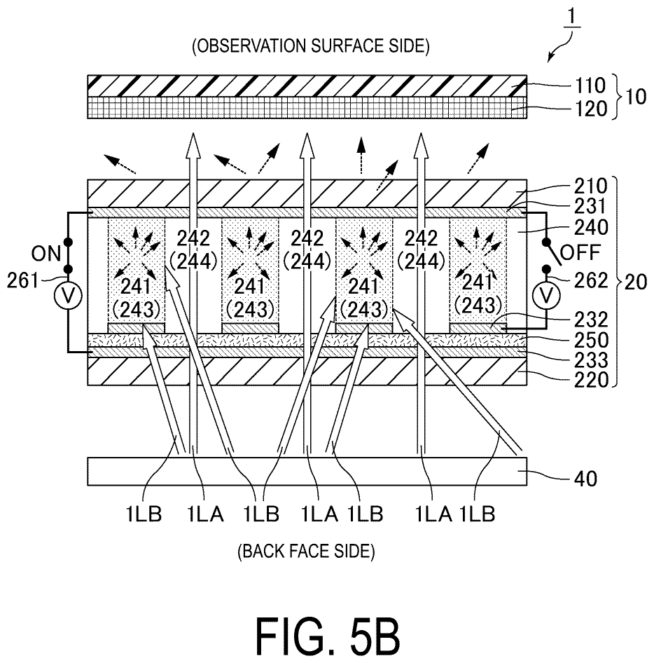

Hereinafter, an image display device including the liquid crystal panel 20 in the present embodiment will be described as an example. FIG. 4 is a schematic cross-sectional view of the image display device according to the present embodiment. FIG. 5A is a schematic cross-sectional view illustrating a wide viewing angle mode of the image display device according to the present embodiment. FIG. 5B is a schematic cross-sectional view illustrating a narrow viewing angle mode of the image display device according to the present embodiment.

As illustrated in FIGS. 4, 5A, and 5B, an image display device 1 in the present embodiment includes the liquid crystal panel 20 in the present embodiment and a display panel 10 that displays images. With this configuration, an image display device capable of controlling the viewing angle while suppressing an increase in thickness can be achieved. The image display device 1 in the present embodiment further includes the backlight 40. In the present embodiment, it is possible to achieve an image display device capable of displaying images on the display panel 10 using light from the backlight 40 and controlling the viewing angle while suppressing an increase in thickness.

The display panel 10 may be any display panel that has a function of displaying images. The display panel 10 is capable of turning on and off the display of images. In the present embodiment, a case in which the display panel 10 is a liquid crystal display panel will be described as an example.

As illustrated in FIG. 4, the image display device 1 includes the display panel 10, the liquid crystal panel 20, and the backlight 40 in order from the observation surface side to the back face side. The display panel 10 includes, in order from the observation surface side to the back face side, a polarizer 140, a color filter (CF) substrate 110 including a CF layer, a liquid crystal layer 130, a thin film transistor (TFT) substrate 120 including TFTs, and a polarizer 140. Between the display panel 10 and the liquid crystal panel 20, there is usually provided an adhesive layer 150 for adhering them. In the present embodiment, the display panel 10 functions as a liquid crystal display panel, so the image display device in the present embodiment is a liquid crystal display device. Although the display panel 10 does not include the liquid crystal layer 130 in FIGS. 5A and 5B, the display panel 10 may include the liquid crystal layer 130 as in FIG. 4.

The TFT substrate 120 includes an insulating substrate, and in the display region, on the insulating substrate, a plurality of gate lines extending parallel to each other and a plurality of source lines extending in parallel to each other in a direction intersecting the gate lines with an insulating film interposed therebetween. The plurality of gate lines and the plurality of source lines are collectively formed in a lattice pattern so as to partition each pixel. A thin film transistor as a switching element is disposed at an intersection of each gate line and each source line.

The TFT substrate 120 includes a planar common electrode disposed on a surface of the insulating substrate on a liquid crystal layer 130 side, the insulating film covering the common electrode, and a pixel electrode disposed on a surface of the insulating film on the liquid crystal layer side and provided with a slit. The pixel electrode is disposed in each region surrounded by two adjacent source lines and two adjacent gate lines, and the pixel electrode is electrically connected to the corresponding source line with a semiconductor layer included in the thin film transistor interposed therebetween. In other words, the display panel 10 in the present embodiment is a fringe field switching (FFS) mode liquid crystal display panel. Positions of the common electrode and the pixel electrode may be exchanged. In this case, a common electrode provided with a slit is disposed on a planar pixel electrode formed so as to occupy each pixel region, with an insulating film interposed therebetween.

In the present embodiment, the display panel 10 in a horizontal alignment mode in which the pixel electrode and the common electrode are provided on one substrate will be described. However, the display mode of the display panel 10 is not limited thereto, and may be in a vertical alignment mode in which the pixel electrode is provided on the TFT substrate 120 and the common electrode is provided on the CF substrate 110. The horizontal alignment mode refers to a mode in which liquid crystal molecules are aligned in a direction substantially horizontal to main surfaces of a pair of substrates when no voltage is applied to the liquid crystal layer, and examples thereof include an in-plane switching (IPS) mode in addition to the above-described FFS mode. The vertical alignment mode refers to a mode in which liquid crystal molecules are aligned in a direction substantially perpendicular to main surfaces of a pair of substrates when no voltage is applied to the liquid crystal layer, and examples thereof include a vertical alignment (VA) mode and a twisted nematic (TN) mode.

Alignment films having a function of controlling alignment of liquid crystal molecules contained in the liquid crystal layer 130 are disposed between the TFT substrate 120 and the liquid crystal layer 130 and between the CF substrate 110 and the liquid crystal layer 130, respectively. The liquid crystal molecules contained in the liquid crystal layer 130 are aligned substantially horizontally to the main surfaces of the pair of substrates in a no voltage applied state in which no voltage is applied between the pixel electrode and the common electrode.

The display panel 10 further includes a source driver electrically connected to the source lines, a gate driver electrically connected to the gate lines, and a controller. The gate driver sequentially supplies scanning signals to the gate lines under control of the controller. The source driver supplies data signals to the source lines under the control of the controller at a timing when the TFTs are brought into a voltage applied state by the scanning signals. Each pixel electrode is set to a potential according to the data signal supplied via a corresponding TFT, and a fringe electrical field is generated between the pixel electrode and the common electrode, causing the liquid crystal molecules in the liquid crystal layer to rotate. In this manner, a magnitude of the voltage applied between the pixel electrode and the common electrode is controlled, retardation of the liquid crystal layer is changed, thereby controlling transmission or non-transmission of light.

For the CF substrate 110, a substrate typically used in the field of liquid crystal display panels can be used. For example, the CF substrate 110 may have a configuration in which components such as color filters and a black matrix (BM) layer are disposed on a surface of a transparent substrate such as a glass substrate. To be more specific, the CF substrate 110 includes, on an insulating substrate, a black matrix provided in a lattice pattern so as to correspond to the gate lines and the source lines, the multiple color filters including a red layer, a green layer, and a blue layer provided so as to be periodically arranged between lattices of the black matrix, an overcoat layer made of a transparent insulating resin provided so as to cover the black matrix and the color filters, and a photo spacer provided in a columnar shape on the overcoat layer.

The pair of polarizers 140 and the adhesive layer 150 (such as OCA) are not limited, and those used in usual liquid crystal display devices can be used. For the liquid crystal layer 130, one commonly used in usual liquid crystal display devices can be used, and thus description thereof is omitted.

The backlight 40 is not limited as long as it emits light to the liquid crystal panel 20. For example, the backlight 40 may include a light source and a reflection sheet. As the light source, a typical backlight source, that is, for example, a cold cathode fluorescent lamp (CCFL), a light emitting diode (LED), or the like can be used.

The backlight 40 may also be a direct type or an edge light type. In a case of the edge light type, for example, the backlight 40 may include a light source, a reflection sheet, and a light guide plate. The light source is disposed on an end face of the light guide plate, and the reflection sheet is disposed on a back face of the light guide plate. As the light guide plate, one commonly used in the field of image display devices can be used. Examples of the reflection sheet include an aluminum plate, a white polyethyleneterephthalate (PET) film, and a reflection film (e.g., enhanced specular reflector (ESR) film manufactured by 3M).

In addition to the components described above, the image display device 1 in the present embodiment includes multiple components such as external circuits such as a tape carrier package (TCP) and a printed circuit board (PCB); optical films such as a viewing angle expansion film and a brightness enhancement film; and a bezel (frame). Some components may be incorporated into another component. Components other than those already described are not limited to specific components, and components commonly used in the field of image display devices can be used, so descriptions thereof will be omitted.

### Modified Example of First Embodiment

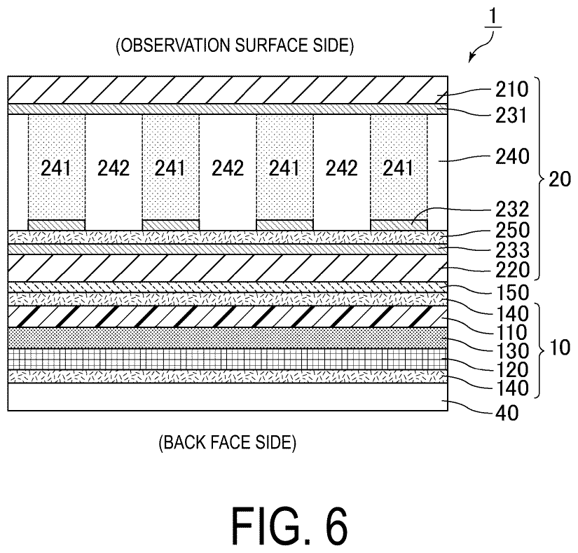

In the image display device 1 in the first embodiment, the display panel 10 is disposed on the observation surface side of the liquid crystal panel 20, but the display panel 10 may be disposed on the back face side of the liquid crystal panel 20. That is, as illustrated in FIG. 6, the image display device 1 may include the liquid crystal panel 20, the display panel 10, and the backlight 40 in order from the observation surface side to the back face side. FIG. 6 is a schematic cross-sectional view of the image display device according to this example.

### Second Embodiment

In the present embodiment, features unique to the present embodiment will be mainly described, and a description of contents overlapping the above-described first embodiment will be omitted. The present embodiment is substantially the same as the first embodiment except that an arrangement shape of a second electrode 232 is different.

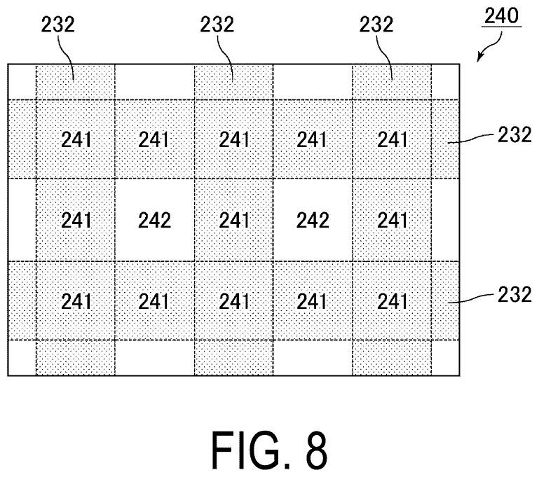

FIG. 8 is a schematic plan view illustrating an arrangement pattern of the second electrode in a liquid crystal panel according to the present embodiment. In the present embodiment, as illustrated in FIG. 8, the second electrode 232 is arranged in a lattice pattern in a plan view. In this case, the viewing angle can be controlled in the vertical direction as well as in the horizontal direction of the screen.

### Third Embodiment

In the present embodiment, features unique to the present embodiment will be mainly described, and a description of contents overlapping the above-described first embodiment will be omitted. The present embodiment is substantially the same as the first embodiment except that a position of a second electrode 232 and design of a power supply are different.

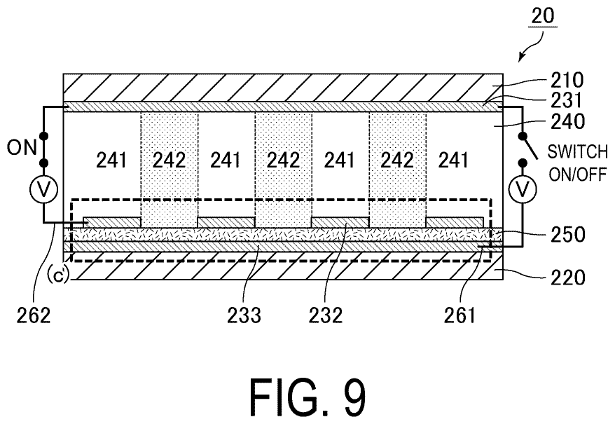

FIG. 9 is a schematic cross-sectional view of a liquid crystal panel according to the present embodiment. As illustrated in FIG. 9, a liquid crystal panel 20 in the present embodiment includes a first transparent substrate 210, a first electrode 231, a liquid crystal layer 240, the second electrode 232, and a second transparent substrate 220 in this order, and further includes an interlayer insulating film 250 and a third electrode 233 in this order from a second electrode 232 side between the second electrode 232 and the second transparent substrate 220.

A main difference between the present embodiment and the first embodiment (FIG. 1) is in (c) in FIG. 9. In the first embodiment described above, the switching region 243 is designed to be switched between the transmitting state (see FIG. 2A) and the scattering state (see FIG. 2B) by applying or not applying a voltage between the first electrode 231 and the second electrode 232 (262). On the other hand, in the present embodiment, a switching region 243 is designed to be switched to a transmitting state or a scattering state by applying or not applying a voltage between the first electrode 231 and the third electrode 233 (261). In this case, in the present embodiment, an overlapping region 241 becomes a transparent region 244, and a non-overlapping region 242 becomes the switching region 243 (see FIG. 9). However, in reality, not only the non-overlapping region 242 becomes the switching region 243, but also a boundary portion between the overlapping region 241 and the non-overlapping region 242 may become the switching region 243 or another portion may become the switching region 243 depending on an electrical field between the electrodes. Accordingly, similarly to the first embodiment, the transparent region 244 and the switching region 243 are not limited to the configuration illustrated in FIG. 9, and can be appropriately controlled by, for example, a width and a pitch of the second electrode 232, a cell thickness (i.e., a thickness D of the non-overlapping region 242), voltages applied to the electrodes, and the like. The same applies to other embodiments described below.

### Fourth Embodiment

In the present embodiment, features unique to the present embodiment will be mainly described, and a description of contents overlapping the above-described first embodiment will be omitted. The present embodiment is substantially the same as the first embodiment except that an arrangement shape of a third electrode 233 is different.

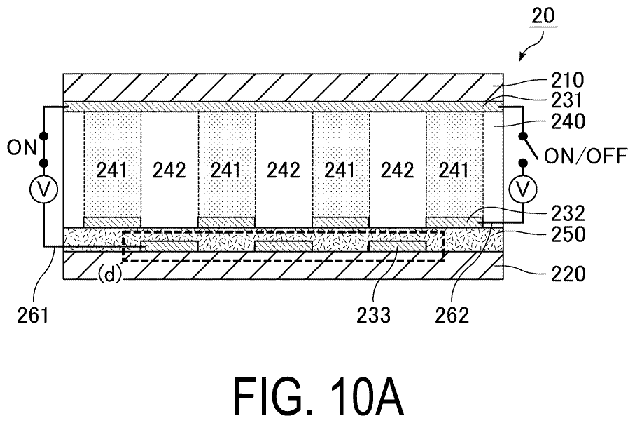

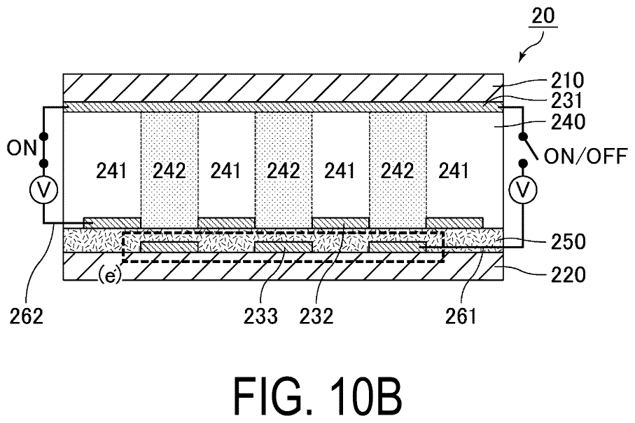

FIG. 10A is a schematic cross-sectional view illustrating an example of a liquid crystal panel according to the present embodiment. FIG. 10B is a schematic cross-sectional view illustrating another example of the liquid crystal panel according to the present embodiment. As illustrated in FIGS. 10A and 10B, a liquid crystal panel 20 in the present embodiment includes a first transparent substrate 210, a first electrode 231, a liquid crystal layer 240, a second electrode 232, and a second transparent substrate 220 in this order, and further includes an interlayer insulating film 250 and a third electrode 233 in this order from a second electrode 232 side between the second electrode 232 and the second transparent substrate 220.

A main difference between the present embodiment and the first embodiment (FIG. 1) is in (d) in FIG. 10A. In the first embodiment, the third electrode 233 is disposed in a planar shape on the entire surface of the second transparent substrate 220. That is, the third electrode 233 is a so-called solid electrode. On the other hand, in the present embodiment, the third electrode 233 is formed by patterning.

### Modified Example of Fourth Embodiment

In the fourth embodiment, a switching region 243 is designed to be switched between a transmitting state and a scattering or absorption state by applying or not applying a voltage between the first electrode 231 and the second electrode 232 (262) (see FIG. 10A). Instead, as in the third embodiment, the switching region 243 may be designed to be switched between the transmitting state and the scattering or absorption state by applying or not applying a voltage between the first electrode 231 and the third electrode 233 (261) (see FIG. 10B). In this example, because of such design (see FIG. 10B), the overlapping region 241 becomes a transparent region 244, and a non-overlapping region 242 becomes the switching region 243. However, as described above, in reality, not only the non-overlapping region 242 becomes the switching region 243, but also a boundary portion between the overlapping region 241 and the non-overlapping region 242 may become the switching region 243 or another portion may become the switching region 243 depending on an electrical field between the electrodes.

A main difference between this example and the third embodiment (FIG. 9) is in (e) in FIG. 10B. In the third embodiment, as in the first embodiment, the third electrode 233 is disposed in a planar shape on an entire surface of the second transparent substrate 220. That is, the third electrode 233 is a so-called solid electrode. On the other hand, in the present embodiment, the third electrode 233 is formed by patterning.

### Fifth Embodiment

In the present embodiment, features unique to the present embodiment will be mainly described, and a description of contents overlapping the above-described first embodiment will be omitted. The present embodiment is substantially the same as the first embodiment except that an electrode including a light absorbing material is used as a second electrode 232.

FIG. 11A is a schematic cross-sectional view illustrating a wide viewing angle mode of a liquid crystal panel according to the present embodiment. FIG. 11B is a schematic cross-sectional view illustrating a narrow viewing angle mode of the liquid crystal panel according to the present embodiment. As illustrated in FIGS. 11A and 11B, a liquid crystal panel 20 in the present embodiment includes a first transparent substrate 210, a first electrode 231, a liquid crystal layer 240, a second electrode 232, and a second transparent substrate 220 in this order, and further includes an interlayer insulating film 250 and a third electrode 233 in this order from a second electrode 232 side between the second electrode 232 and the second transparent substrate 220.

In the present embodiment, the electrode including a light absorbing material is used as the second electrode 232. By using the electrode including a light absorbing material, light emitted obliquely (i.e., specifically, light that is emitted from the liquid crystal panel 20 in an oblique direction) can be reduced, thereby further improving narrow viewing angle performance. As the electrode including a light absorbing material, for example, a light absorbing electrode, a layered body of a light absorbing layer and a transparent electrode, a layered body of a reflective material and a light absorbing electrode, a layered body of a reflective material, a light absorbing layer and a transparent electrode, or the like is preferable.

As the light absorbing material, the transparent electrode, and the reflective material that are components of the electrode including a light absorbing material, those commonly used in the field of electrodes may be used. Examples of the light absorbing material include a metal black matrix (also referred to as a metal BM) made of a metal material, and a resin black matrix (also referred to as a resin BM) made of a resin material. Examples of the metal BM include a metal film containing aluminum, molybdenum, chromium, titanium, or an alloy thereof, and the metal BM may be a single-layer film or a multilayer film. Examples of the resin BM include black resists, and among them, a black photosensitive resin is preferable. Specific examples thereof include a black photosensitive acrylic resin. A transmittance of the light absorbing material is preferably, for example, from 0% to 1%.

Examples of the transparent electrode are as described above, and among them, ITO is preferable. As the reflective material, for example, a highly reflective metal such as silver, aluminum, alumina, talc, titanium, or an alloy of silver, palladium, and copper (APC) can be used. In addition, as the reflective material, a dielectric multilayer film (reflection enhancing film) in which a high-refractive-index layer of Ta₂O₃ or the like and a low-refractive-index layer of MgF₂ or the like are layered, or a layered body of a high reflection metal and a reflection enhancing film may be used. The reflective material can be formed, for example, by forming a metal film by vapor deposition, sputtering, or the like and then patterning the metal film. A light reflectance of the reflective material is preferably, for example, from 90% to 100%.

In the present embodiment, a case in which a light absorbing electrode is used in particular as the second electrode 232 will be described. The light absorbing electrode is preferably a metal BM. The metal BM is usually formed as a finely patterned metal thin film on a substrate. Examples of the material of the metal thin film include aluminum, molybdenum, chromium, titanium, and alloys thereof. Common methods for film formation include vapor deposition, sputtering, vacuum film formation, and the like. Patterning of the metal thin film is carried out, for example, by coating and drying a photoresist on the metal thin film, irradiating the photoresist with ultraviolet rays through a photomask, dissolving unexposed areas with a developing solution to form a resist pattern, and then etching the metal or peeling off the resist.

In the narrow viewing angle mode in the first embodiment (see FIG. 2B), light directly enters the switching region 243 (scattering state) from the backlight 40 (see (b) in FIG. 2B), is scattered in the switching region 243 and exits the liquid crystal panel 20 as light in the oblique direction (see (a) in FIG. 2B). On the other hand, in the narrow viewing angle mode in the present embodiment (see FIG. 11B), light that is about to directly enter the switching region 243 (scattering state) from the backlight 40 (see (h) in FIG. 11B) is cut by the light absorbing electrode (second electrode 232), so that light that is scattered and exits the liquid crystal panel 20 as light in an oblique direction (see (g) in FIG. 11B) can be reduced. Therefore, in the present embodiment, narrow viewing angle performance is further improved than in the first embodiment. Note that since there is light that does not directly enter the switching region 243 from the backlight 40 but enters the switching region 243 passed through the transparent region 244 (i.e., light that enters the switching region 243 from the backlight 40 without passing through the light absorbing electrode (the second electrode 232)), even in the narrow viewing angle mode in the present embodiment, there is a small amount of light emitted obliquely due to scattering of the light.

### Modified Example of Fifth Embodiment

In the fifth embodiment, a case is described in which the light absorbing electrode among the electrodes including a light absorbing material is used as the second electrode 232. However, a layered body of a light absorbing layer and a transparent electrode may be used as the second electrode 232. Also in this case, similar to the fifth embodiment, the narrow viewing angle performance is further improved than in the first embodiment.

As the light absorbing layer, a resin BM is preferable. Specific examples of the layered body of the light absorbing layer and the transparent electrode include a layered body in which a transparent electrode (such as ITO) is layered on the resin BM.

### Sixth Embodiment

In the present embodiment, features unique to the present embodiment will be mainly described, and a description of contents overlapping the above-described first embodiment will be omitted. The present embodiment is substantially the same as the first embodiment except that an electrode including a light absorbing material is used as a second electrode 232.

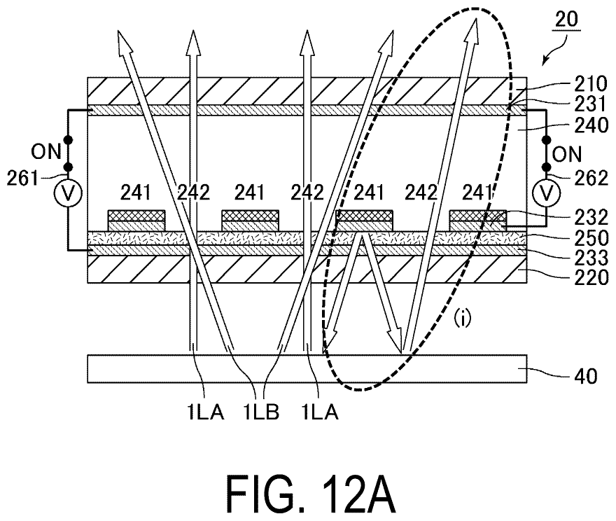

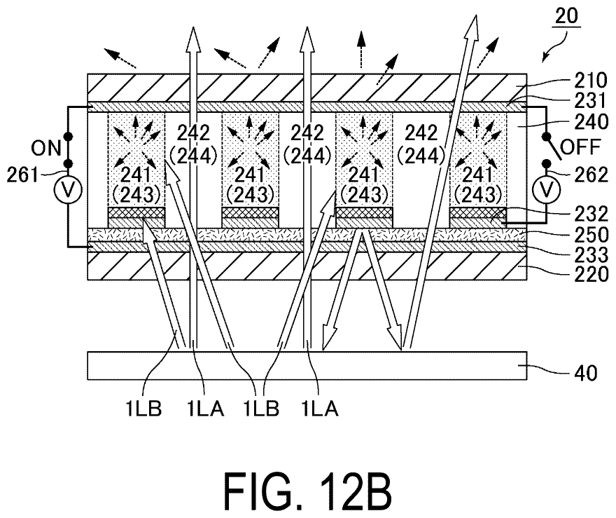

FIG. 12A is a schematic cross-sectional view illustrating a wide viewing angle mode of a liquid crystal panel according to the present embodiment. FIG. 12B is a schematic cross-sectional view illustrating a narrow viewing angle mode of the liquid crystal panel according to the present embodiment. As illustrated in FIGS. 12A and 12B, a liquid crystal panel 20 in the present embodiment includes a first transparent substrate 210, a first electrode 231, a liquid crystal layer 240, a second electrode 232, and a second transparent substrate 220 in this order, and further includes an interlayer insulating film 250 and a third electrode 233 in this order from a second electrode 232 side between the second electrode 232 and the second transparent substrate 220.

In the present embodiment, the electrode including a light absorbing material is used as the second electrode 232. By using the electrode including a light absorbing material, light emitted obliquely can be reduced, thereby further improving narrow viewing angle performance. Among electrodes including a light absorbing material, in the present embodiment, a case in which a layered body of a reflective material and a light absorbing electrode is used in particular as the second electrode 232 will be described.

Among the above-described metals, silver (Ag) is preferable as the reflective material. As described above, the metal BM is preferable as the light absorbing electrode. Accordingly, as the layered body of the reflective material and the light absorbing electrode, a layered body in which the metal BM is layered on silver is preferable. Note that when an electrode including a reflective material is used as the second electrode 232, the reflective material is preferably positioned on a backlight 40 side. That is, when a layered body of a reflective material and a light absorbing electrode is used, it is preferable to dispose the layered body so that the reflective material is on the backlight 40 side.

Similarly to the fifth embodiment, narrow viewing angle performance is further improved in the present embodiment than in the first embodiment. However, in the fifth embodiment, as a trade-off with improving the narrow viewing angle performance, light may be cut by the second electrode 232 (light absorbing electrode) even in a wide viewing angle mode in which there is no need to cut light 1LB in an oblique direction (see (f) in FIG. 11A). On the other hand, in the present embodiment, since the second electrode 232 (the layered body of the reflective material and the light absorbing electrode) includes the reflective material, the light that is about to enter an overlapping region 241 (a switching region 243 in the scattering state) from the backlight 40 can be reflected to the back face side (the backlight 40 side) by the reflective material. Furthermore, when the backlight 40 includes a reflection sheet, the light reflected by the reflective material can be reflected back toward an observation surface side by the reflection sheet to be recycled as light that enters the non-overlapping region 242 (transparent region 244) (see (i) in FIG. 12A). As a result, while cutting light, which is desired to be cut, that is about to directly enter the overlapping region 241 (the switching region 243 in the scattering state) in the narrow viewing angle mode, the cut light can be changed (recycled) to light in a front direction without being absorbed and wasted. Therefore, in the present embodiment, luminance can be increased in both the wide viewing angle mode and the narrow viewing angle mode.

### Modified Example of Sixth Embodiment

In the sixth embodiment, a case is described in which the layered body of the reflective material and the light absorbing electrode among the electrodes including a light absorbing material is used as the second electrode 232. However, a layered body of a reflective material, a light absorbing layer, and a transparent electrode may be used as the second electrode 232. Also in this modified example, similarly to the sixth embodiment, the narrow viewing angle performance is further improved, and the luminance can be increased in both the wide viewing angle mode and the narrow viewing angle mode by including the reflective material in the second electrode 232.

As described above, silver (Ag) is preferable as the reflective material. As described above, the resin BM is preferable as the light absorbing layer. Accordingly, as the layered body of the reflective material, the light absorbing layer, and the transparent electrode, a layered body in which the resin BM and the transparent electrode (such as ITO) are layered on silver is preferable. Also in this case, it is preferable to dispose the layered body so that the reflective material is on the backlight 40 side.

### Seventh Embodiment

In the present embodiment, features unique to the present embodiment will be mainly described, and a description of contents overlapping the above-described first embodiment will be omitted. The present embodiment is substantially the same as the first embodiment except mainly that PDLC that scatters light in a voltage applied state is used as a liquid crystal layer 240.

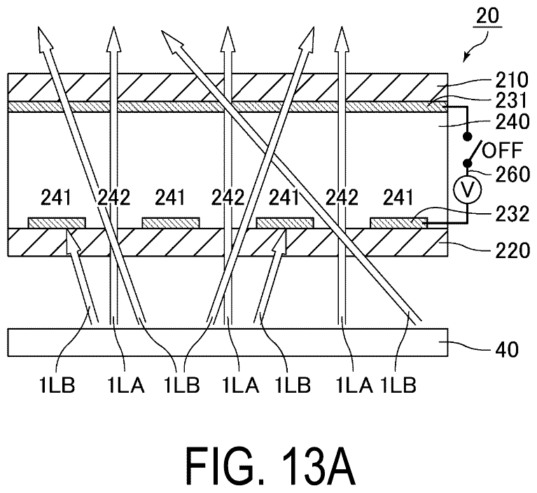

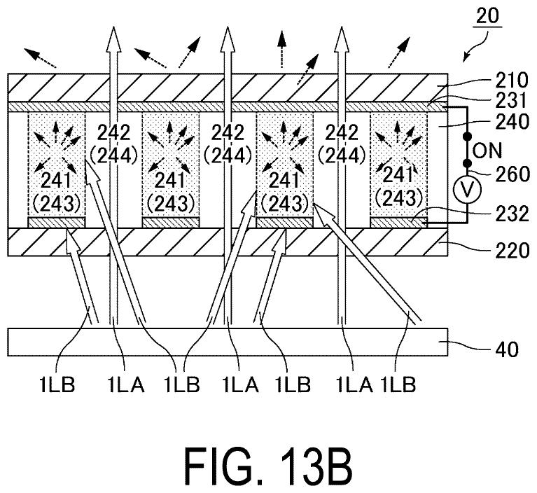

FIG. 13A is a schematic cross-sectional view illustrating a wide viewing angle mode of a liquid crystal panel according to the present embodiment. FIG. 13B is a schematic cross-sectional view illustrating a narrow viewing angle mode of the liquid crystal panel according to the present embodiment. As illustrated in FIGS. 13A and 13B, a liquid crystal panel 20 in the present embodiment includes a first transparent substrate 210, a first electrode 231, a liquid crystal layer 240, a second electrode 232, and a second transparent substrate 220 in this order. In the present embodiment, the electrode on a second substrate 220 side can be one layer (only the second electrode 232), and an interlayer insulating film 250 is also unnecessary, so that the manufacturing process can be further shortened (see FIGS. 13A and 13B).

As illustrated in FIGS. 13A and 13B, light enters the liquid crystal panel 20 from the back face side (specifically, a backlight 40). In a case in which the PDLC having a property of scattering light under a voltage applied state is used as the liquid crystal layer 240, when no voltage is applied between the first electrode 231 and the second electrode 232 (260) (no voltage applied state), an overlapping region 241 and a non-overlapping region 242 are integrated without being distinguished from each other, and an entire liquid crystal layer 240 is in a transmitting state (transparent region) (see FIG. 13A). That is, a transparent region 244 and a switching region 243 are in a state having a transmittance T1. In this case, of light that enters the liquid crystal panel 20 from the backlight 40, light that enters the liquid crystal layer 240 without passing through the second electrode 232 passes directly through the liquid crystal panel 20 (see FIG. 13A). As a result, light from the backlight 40 can be transmitted from a low polar angle side to a high polar angle side with sufficiently reduced transmission loss, thereby enabling the wide viewing angle mode with high luminance.

On the other hand, when a voltage is applied between the first electrode 231 and the second electrode 232 (260) (voltage applied state), the liquid crystal layer 240 itself acts as a louver. That is, of the light that enters the liquid crystal panel 20 from the backlight 40, light 1LB in an oblique direction is scattered (attenuated) in the overlapping region 241 (switching region 243), and passes through the liquid crystal panel 20 as attenuated light (see FIG. 13B). Here, the overlapping region 241 (switching region 243) is in the scattering state, whereas the non-overlapping region 242 (transparent region 244) remains in the transmitting state. That is, the transparent region 244 has a transmittance T2, and the switching region 243 has a transmittance T3 due to scattering (where T1≥T2>T3). Of the light that enters the liquid crystal panel 20 from the backlight 40, light 1LA in a front direction passes through the liquid crystal panel 20 without being attenuated (see FIG. 13B). As a result, light from the backlight 40 is attenuated on the high polar angle side, and light from the back face side can be transmitted with the same luminance only on the low polar angle side, thereby enabling the narrow viewing angle mode.

### Eighth Embodiment

In the present embodiment, features unique to the present embodiment will be mainly described, and a description of contents overlapping the above-described first embodiment will be omitted. The present embodiment is substantially the same as the first embodiment except that PDLC that scatters light in a voltage applied state is used as a liquid crystal layer 240.

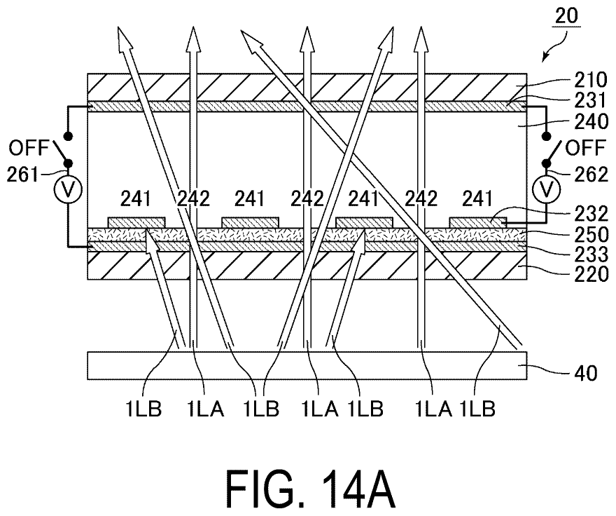

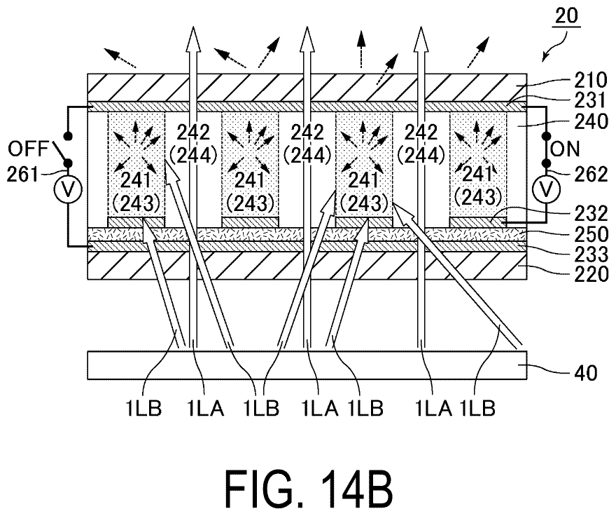

FIG. 14A is a schematic cross-sectional view illustrating a wide viewing angle mode of a liquid crystal panel according to the present embodiment. FIG. 14B is a schematic cross-sectional view illustrating a narrow viewing angle mode of the liquid crystal panel according to the present embodiment. As illustrated in FIGS. 14A and 14B, a liquid crystal panel 20 in present embodiment includes a first transparent substrate 210, a first electrode 231, a liquid crystal layer 240, a second electrode 232, and a second transparent substrate 220 in this order, and further includes an interlayer insulating film 250 and a third electrode 233 in order from a second electrode 232 side between the second electrode 232 and the second transparent substrate 220.

In the seventh embodiment, the electrode on the second substrate 220 side is one layer (only the second electrode 232), and the interlayer insulating film 250 is also unnecessary. However, as in the present embodiment, the liquid crystal panel 20 may include the interlayer insulating film 250 and the third electrode 233 in order from the second electrode 232 side between the second electrode 232 and the second transparent substrate 220. In this case, as described in the first embodiment, different voltages can be applied to the transparent region 244 and the switching region 243, which is very useful.

### Ninth Embodiment

In the present embodiment, features unique to the present embodiment will be mainly described, and a description of contents overlapping the above-described first embodiment will be omitted. The present embodiment is substantially the same as the first embodiment except that a material of a liquid crystal layer 240 is different.

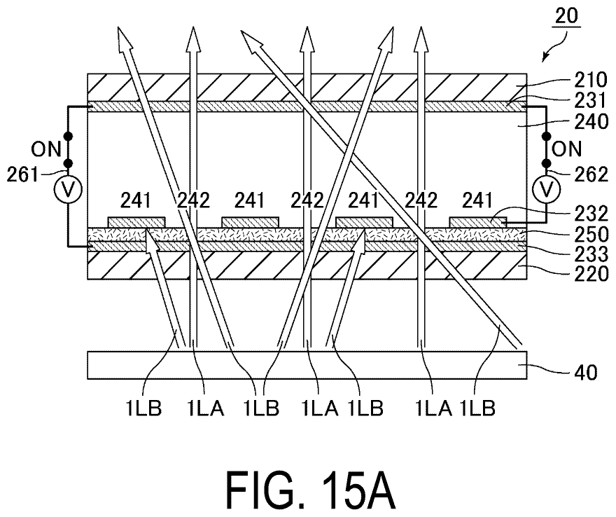

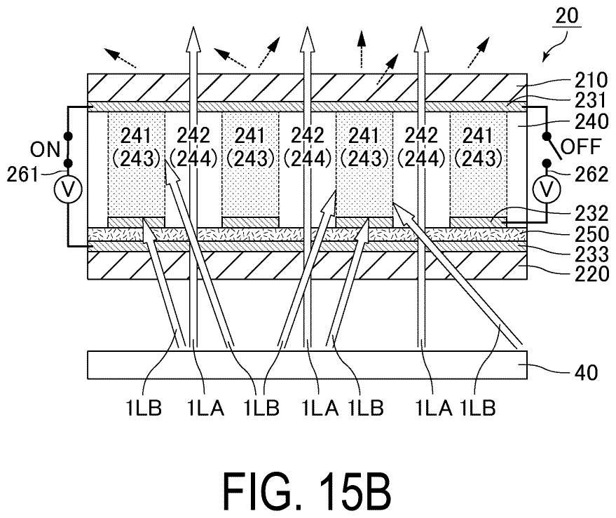

FIG. 15A is a schematic cross-sectional view illustrating a wide viewing angle mode of a liquid crystal panel according to the present embodiment. FIG. 15B is a schematic cross-sectional view illustrating a narrow viewing angle mode of the liquid crystal panel according to the present embodiment. As illustrated in FIGS. 15A and 15B, a liquid crystal panel 20 in the present embodiment includes a first transparent substrate 210, a first electrode 231, a liquid crystal layer 240, a second electrode 232, and a second transparent substrate 220 in this order, and further includes an interlayer insulating film 250 and a third electrode 233 in this order from a second electrode 232 side between the second electrode 232 and the second transparent substrate 220.

In the present embodiment, the liquid crystal layer 240 contains guest-host liquid crystal (also referred to as GH liquid crystal) containing a dichroic dye. The guest-host liquid crystal containing a dichroic dye is obtained by adding a dichroic dye (guest) to a liquid crystal material (host). A percentage of the dichroic dye (guest) is preferably 0.5 to 15 mass % with the total amount of the liquid crystal layer 240 as 100 mass %. The percentage of the dichroic dye is more preferably 1 to 10 mass %, and still more preferably 2 to 5 mass %. A color of the dichroic dye is not limited, and examples thereof include black and red.

The liquid crystal layer 240 includes an overlapping region 241 overlapping the second electrode 232 and a non-overlapping region 242 not overlapping the second electrode 232. Since the liquid crystal layer 240 contains the GH liquid crystal containing a dichroic dye and includes the overlapping region 241 and the non-overlapping region 242, the liquid crystal layer 240 includes a transparent region 244 and a switching region 243 that is switched between a transmitting state and a scattering or absorption state. Depending on design of a power supply, the overlapping region 241 can be the switching region 243 and the non-overlapping region 242 can be the transparent region 244, or the overlapping region 241 can be the transparent region 244 and the non-overlapping region 242 can be the switching region 243. In the present embodiment, the switching region 243 is designed to be switched between the transmitting state and the scattering state by applying or not applying a voltage between the first electrode 231 and the second electrode 232 (262), so that the overlapping region 241 becomes the switching region 243 and the non-overlapping region 242 becomes the transparent region 244 (see FIGS. 15A and 15B). However, as described above, in reality, not only the overlapping region 241 becomes the switching region 243, but also a boundary portion between the overlapping region 241 and the non-overlapping region 242 may become the switching region 243 or another portion may become the switching region 243 depending on an electrical field between the electrodes.

In the present embodiment, the switching region 243 is a region that is switched between the transmitting state and the absorption state. The absorption state is a state in which light is absorbed. In the present embodiment, the liquid crystal layer 240 in the absorption state is in a state similar to light shielding glass.

In the present embodiment, as will be described later, in the wide viewing angle mode (see FIG. 15A), the transparent region 244 and the switching region 243 have a certain transmittance (also referred to as visible light transmittance or light transmittance) T1. On the other hand, in the narrow viewing angle mode (see FIG. 15B), the transparent region 244 has a transmittance T2, and the switching region 243 has a transmittance T3 due to absorption (where T1, T2, and T3 satisfy a relationship of “T1≥T2>T3”). The transmittance T1 may be 100%. T3 may be 0%.

As illustrated in FIGS. 15A and 15B, light enters the liquid crystal panel 20 from the back face side (specifically, a backlight 40). In a case in which the liquid crystal layer 240 contains the GH liquid crystal, when a voltage is applied between the first electrode 231 and the second electrode 232 (262) (voltage applied state) and a voltage is applied between the first electrode 231 and the third electrode 233 (261), the overlapping region 241 and the non-overlapping region 242 are integrated without being distinguished from each other, and an entire liquid crystal layer 240 is in a transmitting state (transparent region) (see FIG. 15A). That is, the transparent region 244 and the switching region 243 are in a state having the transmittance T1. In this case, of light that enters the liquid crystal panel 20 from the backlight 40, light that enters the liquid crystal layer 240 without passing through the second electrode 232 passes directly through the liquid crystal panel 20 (see FIG. 15A). As a result, light from the backlight 40 can be transmitted from a low polar angle side to a high polar angle side with sufficiently reduced transmission loss, thereby enabling the wide viewing angle mode with high luminance.

On the other hand, when no voltage is applied between the first electrode 231 and the second electrode 232 (262) (no voltage applied state) and when a voltage is applied between the first electrode 231 and the third electrode 233 (261), the liquid crystal layer 240 itself acts as a louver. That is, of the light that enters the liquid crystal layer 240 from the backlight 40, light 1LB in an oblique direction is absorbed (attenuated) in the overlapping region 241 (switching region 243), and passes through the liquid crystal panel 20 as attenuated light (see FIG. 15B). Here, the overlapping region 241 (switching region 243) is in the absorption state, whereas the non-overlapping region 242 (transparent region 244) remains in the transmitting state. That is, the transparent region 244 has the transmittance T2, and the switching region 243 has the transmittance T3 due to absorption (where T1≥T2>T3). Of the light that enters the liquid crystal panel 20 from the backlight 40, light 1LA in a front direction passes through the liquid crystal panel 20 without being attenuated (see FIG. 15B). As a result, light from the backlight 40 is attenuated on the high polar angle side, and light from the back face side can be transmitted with the same luminance only on the low polar angle side, thereby enabling the narrow viewing angle mode.

### Modified Example of Ninth Embodiment

In the ninth embodiment, an example is described in which the GH liquid crystal containing a dichroic dye is used as the liquid crystal layer 240, but PDLC containing a dichroic dye can also be used as the liquid crystal layer 240.

FIGS. 15A and 15B are also schematic cross-sectional views illustrating a wide viewing angle mode and a narrow viewing angle mode of the liquid crystal panel according to this example, respectively. As illustrated in FIGS. 15A and 15B, a liquid crystal panel 20 in the present embodiment includes a first transparent substrate 210, a first electrode 231, a liquid crystal layer 240, a second electrode 232, and a second transparent substrate 220 in this order, and further includes an interlayer insulating film 250 and a third electrode 233 in this order from a second electrode 232 side between the second electrode 232 and the second transparent substrate 220.

The liquid crystal layer 240 contains PDLC containing a dichroic dye in the present embodiment. That is, the liquid crystal layer 240 contains the PDLC containing a dichroic dye as a main component.

Note that the liquid crystal layer 240 included in the liquid crystal panel 20 in the disclosure may have any one of a configuration containing the PDLC (see, for example, the first to eighth embodiments and the modified example of the ninth embodiment), a configuration containing the GH liquid crystal (see, for example, the ninth embodiment), and a configuration containing both the PDLC and the GH liquid crystal.

### Tenth Embodiment

In the present embodiment, features unique to the present embodiment will be mainly described, and a description of contents overlapping the above-described first embodiment will be omitted. The present embodiment is substantially the same as the first embodiment except that a backlight driven by local dimming is used as a backlight 40.

FIGS. 4, 5A, and 5B are also a schematic cross-sectional view illustrating an image display device in the present embodiment, a schematic cross-sectional view illustrating a wide viewing angle mode of the image display device in the present embodiment, and a schematic cross-sectional view illustrating a narrow viewing angle mode of the image display device in the present embodiment. In the present embodiment, a backlight driven by local dimming is used as the backlight 40.

“Driven by local dimming” is a function of dividing an image display region in a display device into multiple areas (also referred to as segments) and controlling light for each area. Use of the backlight driven by local dimming allows local control of luminance of the backlight, resulting in high contrast and low power consumption of the display device. However, in general, it is difficult to achieve both control of the viewing angle and driving of the backlight by local dimming, in the display device in which the viewing angle is controlled by the backlight. On the other hand, in the disclosure, the viewing angle can be controlled by the liquid crystal panel 20, so any backlight driving method can be used. Therefore, it is possible to combine the liquid crystal panel 20 with the backlight driven by local dimming, which is very useful.

### Eleventh Embodiment

In the present embodiment, features unique to the present embodiment will be mainly described, and a description of contents overlapping the above-described first embodiment will be omitted. The present embodiment is substantially the same as the first embodiment except that the display panel 10 is a self-luminous display panel.

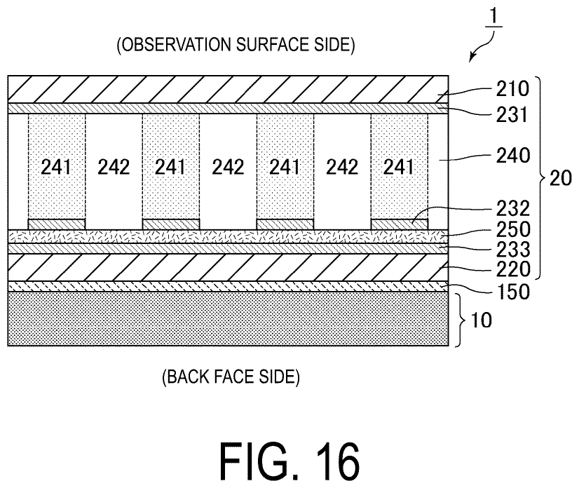

FIG. 16 is a schematic cross-sectional view of an image display device according to the present embodiment. As illustrated in FIG. 16, an image display device 1 in the present embodiment includes a liquid crystal panel 20 in the present embodiment and a self-luminous display panel as a display panel 10 for displaying images. Between the display panel 10 and the liquid crystal panel 20, there is usually provided an adhesive layer 150 for adhering them. Since the image display device in the present embodiment has the self-luminous display panel as the display panel 10, a backlight is not necessary.

The self-luminous display panel is not limited as long as the display panel is a self-luminous type. Examples of the self-luminous display panel include an organic electroluminescence (EL) display panel and a micro-LED display panel using micrometer (μm) scale LEDs as RGB elements. In the disclosure, the viewing angle can be controlled by the liquid crystal panel 20 regardless of the presence or absence of a backlight. Therefore, it is possible to combine the liquid crystal panel 20 with the self-luminous display panel, which is very useful.

The embodiments in the disclosure are described above, and all the individual matters described can be applied to the disclosure in general.

The disclosure is described in further detail below using examples, but the disclosure is not limited to these examples alone.

### Example 1

An image display device in Example 1 corresponds to the image display device in the first embodiment (see FIGS. 4, 5A, 5B, and 7). A size of the display panel 10 was set to 11-inch, resolution was set to FHD, and a pixel pitch (a pixel width in an extending direction of the gate line x a pixel width in an extending direction of the source line) was set to 42 μm×126 μm. Table 1 shows various design values of the liquid crystal panel 20. In the following examples, the display panel 10 and the backlight 40 were the same as those in Example 1 unless otherwise specified. Various designs and structures of the liquid crystal panel 20 are also the same as those in Example 1 unless otherwise specified.

TABLE 1

| | | Example 1 |
|---|---|---|
| Display | Size | 11-inch |
| panel 10 | Resolution | FHD |
| | Pixel pitch [μm] | 42 × 126 |
| Liquid | Viewing angle θ [°] | 33 |
| crystal | Width W1 of non-overlapping region [μm] | 3 |
| panel 20 | Width W2 of overlapping region [μm] | 3 |
| | Pitch of non-overlapping region [μm] | 6 |
| | Height D of non-overlapping region [μm] | 10 |

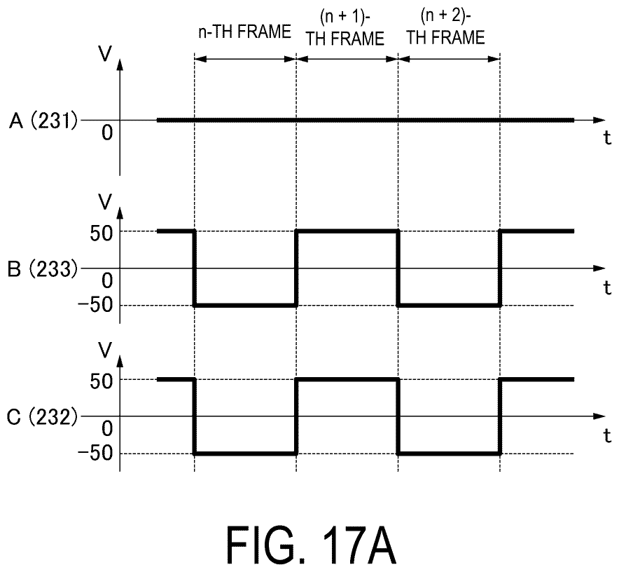

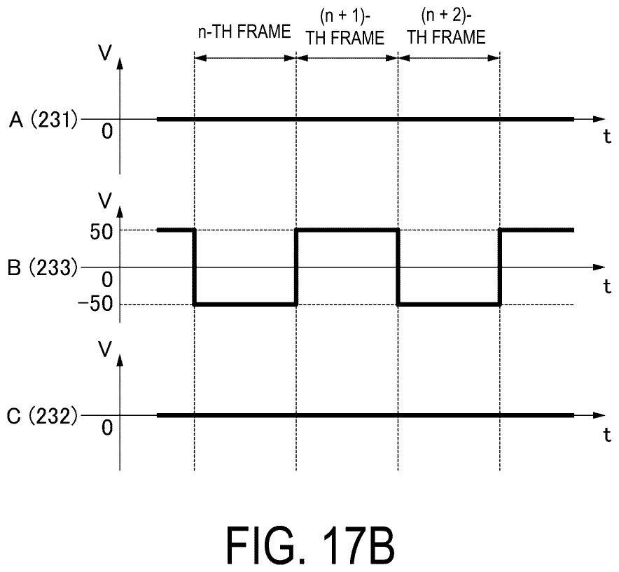

FIG. 17A shows waveform diagrams of voltages of the respective electrodes in the wide viewing angle mode in the image display device in this example. FIG. 17B shows waveform diagrams of voltages of the respective electrodes in the narrow viewing angle mode in the image display device in this example. A(231) is a waveform diagram of a voltage of the first electrode 231, B(233) is a waveform diagram of a voltage of the third electrode 233, and C(232) is a waveform diagram of a voltage of the second electrode 232. The horizontal axis represents time and the vertical axis represents voltage (V). The drive voltage is not limited to this voltage setting, but may be set as appropriate.

In this example, the first electrode 231(A) functioned as the common electrode, the non-overlapping region 242 (mainly the transparent region 244) was controlled by the first electrode 231(A) and the third electrode 233(B), and the overlapping region 241 (mainly the switching region 243) was controlled by the first electrode 231(A) and the second electrode 232(C).

The image display device in this example was compatible with a normal liquid crystal process, had no moire, and had excellent viewing angle performance. In particular, it was possible to achieve a wide viewing angle mode with high luminance, and also suppress an increase in thickness, weight, and manufacturing costs of the image display device.

### Example 2

An image display device in Example 2 corresponds to the image display device in the second embodiment. This example is the same as Example 1 except that an arrangement pattern of the second electrode 232 is changed to a lattice pattern (in a plan view) as illustrated in FIG. 8. In the image display device in this example, it was possible to control the viewing angle not only in the horizontal direction but also in the vertical direction of the screen.

### Example 3

An image display device in Example 3 corresponds to the image display device in the third embodiment (see FIG. 9). In this example, the switching region 243 was designed to be switched to the transmitting state or the scattering state by applying or not applying a voltage between the first electrode 231 and the third electrode 233 (261). In this example, the overlapping region 241 mainly becomes the transparent region 244, and the non-overlapping region 242 mainly becomes the switching region 243.

### Examples 4-1 and 4-2

An image display device in Example 4-1 corresponds to the image display device in the fourth embodiment (see FIG. 10A), and an image display device in Example 4-2 corresponds to the image display device in the modified example of the fourth embodiment (see FIG. 10B). The third electrode 233 was formed by patterning as illustrated in (d) in FIG. 10A and in (e) in FIG. 10B.

The image display devices in these examples were also compatible with a normal liquid crystal process, had no moire, and had excellent viewing angle performance. In particular, it was possible to achieve a wide viewing angle mode with high luminance, and also suppress an increase in thickness, weight, and manufacturing costs of the image display device.

### Example 5

An image display device in Example 5 corresponds to the image display device in the fifth embodiment (see FIGS. 11A and 11B). In this example, a light absorbing electrode (metal BM) was used as the second electrode 232. In this example, narrow viewing angle performance was further improved than in Example 1.

### Example 6

An image display device in Example 6 corresponds to the image display device in the sixth embodiment (see FIGS. 12A and 12B). In this example, a layered body of a reflective material and a light absorbing electrode was used as the second electrode 232. In this example, luminance was further improved in both the wide viewing angle mode and the narrow viewing angle mode than in Example 1.

### Example 7

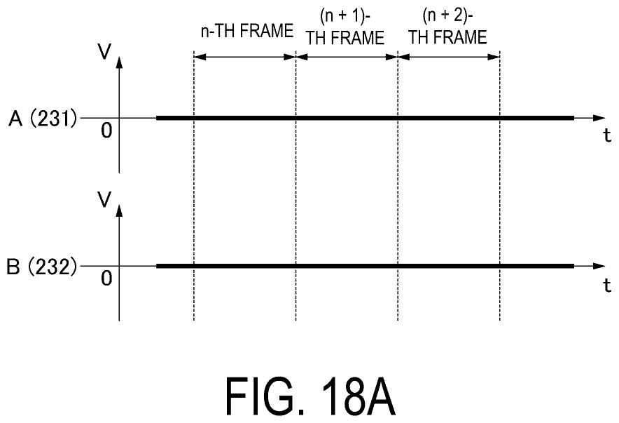

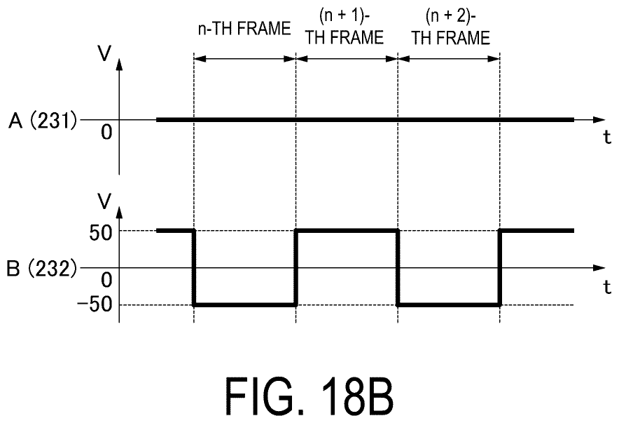

An image display device in Example 7 corresponds to the image display device in the seventh embodiment (see FIGS. 13A and 13B). FIG. 18A shows waveform diagrams of voltages of the respective electrodes in the wide viewing angle mode in the image display device in this example. FIG. 18B shows waveform diagrams of voltages of the respective electrodes in the narrow viewing angle mode in the image display device in this example. A(231) is a waveform diagram of a voltage of the first electrode 231, and B(232) is a waveform diagram of the voltage of the second electrode 232. The horizontal axis represents time and the vertical axis represents voltage (V). The drive voltage is not limited to this voltage setting, but may be set as appropriate.

In this example, the first electrode 231(A) functioned as the common electrode, and the overlapping region 241 (mainly the switching region 243) was controlled by the first electrode 231(A) and the second electrode 232(C).

In this example, the third electrode and the interlayer insulating film were able to be eliminated, and the manufacturing process was able to be further shortened.

### Example 8

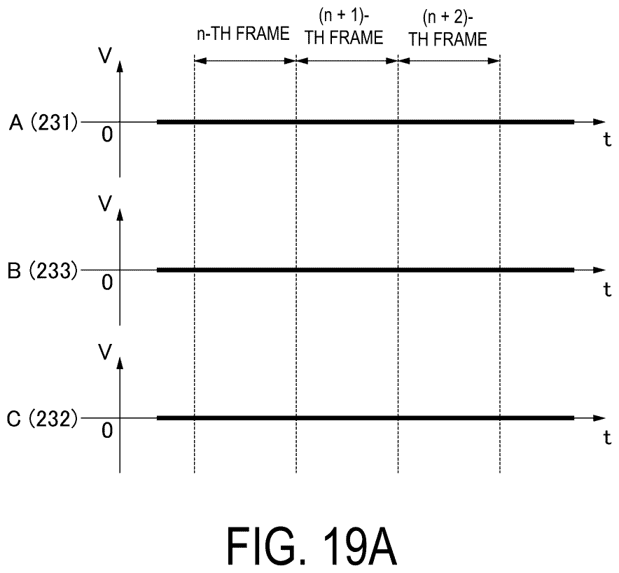

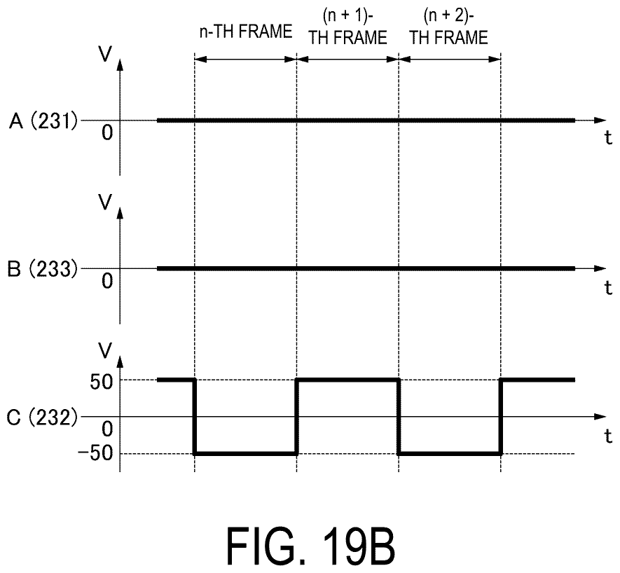

An image display device in Example 8 corresponds to the image display device in the eighth embodiment (see FIGS. 14A and 14B). FIG. 19A shows waveform diagrams of voltages of the respective electrodes in the wide viewing angle mode in the image display device in this example. FIG. 19B shows waveform diagrams of voltages of the respective electrodes in the narrow viewing angle mode in the image display device in this example. A(231) is a waveform diagram of a voltage of the first electrode 231, B(233) is a waveform diagram of a voltage of the third electrode 233, and C(232) is a waveform diagram of a voltage of the second electrode 232. The horizontal axis represents time and the vertical axis represents voltage (V). The drive voltage is not limited to this voltage setting, but may be set as appropriate.

In this example, the first electrode 231(A) functioned as the common electrode, the non-overlapping region 242 (mainly the transparent region 244) was controlled by the first electrode 231(A) and the third electrode 233(B), and the overlapping region 241 (mainly the switching region 243) was controlled by the first electrode 231(A) and the second electrode 232(C).

### Examples 9-1 and 9-2

An image display device in Example 9-1 corresponds to the image display device in the ninth embodiment, and an image display device in Example 9-2 corresponds to the image display device in the modified example of the ninth embodiment (see FIGS. 15A and 15B for both examples).

The image display devices in these examples were also compatible with a normal liquid crystal process, had no moire, and had excellent viewing angle performance. In particular, it was possible to achieve a wide viewing angle mode with high luminance, and also suppress an increase in thickness, weight, and manufacturing costs of the image display device.

### Example 10

An image display device in Example 10 corresponds to the image display device in the tenth embodiment. The structure of the image display device and the path of light or the like in each viewing angle mode are illustrated in FIGS. 4, 5A, 5B, and 7. Also when the backlight driven by local dimming is combined as in this example, it was possible to achieve an image display device having excellent viewing angle performance while suppressing an increase in thickness, weight, and manufacturing costs.

### Example 11

An image display device in Example 11 corresponds to the image display device in the eleventh embodiment (see FIG. 16). Also when the self-luminous display panel is combined as in this example, it was possible to achieve an image display device having excellent viewing angle performance while suppressing an increase in thickness, weight, and manufacturing costs.

The embodiments of the disclosure described above may be combined as appropriate within a range that does not depart from the gist of the disclosure.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A liquid crystal panel comprising:
a first transparent substrate;
a first electrode;
a liquid crystal layer;
a second electrode; and
a second transparent substrate in this order,
wherein the liquid crystal layer contains polymer dispersed liquid crystal and/or guest-host liquid crystal containing a dichroic dye, and includes a transparent region and a switching region switched between a transmitting state and a scattering or absorption state by including an overlapping region overlapping the second electrode and a non-overlapping region not overlapping the second electrode.

2. The liquid crystal panel according to claim 1,
wherein the second electrode is disposed in a stripe shape or a lattice pattern in a plan view.

3. The liquid crystal panel according to claim 1, comprising
an interlayer insulating film and a third electrode provided in this order from a side of the second electrode between the second electrode and the second transparent substrate.

4. The liquid crystal panel according to claim 3,
wherein the transparent region and the switching region are configured to be applied with different voltages.

5. The liquid crystal panel according to claim 1,
wherein a thickness of the non-overlapping region is 30 μm or less.

6. The liquid crystal panel according to claim 1,
wherein the second electrode is a transparent electrode or an electrode including a light absorbing material.

7. An image display device comprising the liquid crystal panel according to claim 1; and
a display panel configured to display an image.

8. The image display device according to claim 7, further comprising
a backlight.

9. The image display device according to claim 8,
wherein the backlight has a local dimming function.

10. The image display device according to claim 7,
wherein the display panel is a liquid crystal display panel or a self-luminous display panel.
